(19) United States
(12) Patent Application Publication
(10) Pub. No.: US 2025/0113513 A1
(43) Pub. Date: Apr. 3, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Chun-Wing YEUNG, Hsinchu City (TW); Wen-Chiang HONG, Taipei City (TW); Yu-Jen CHANG, New Taipei City (TW); Wei-Chen CHANG, Hsinchu County (TW); Feng-Ming CHANG, Taitung City (TW)

(21) Appl. No.: 18/479,200

(22) Filed: Oct. 2, 2023

(51) Int. Cl. H01L 29/66; H01L 23/528; H01L 29/06; H01L 29/40; H01L 29/417; H01L 29/423; H01L 29/775

(52) U.S. Cl. CPC H10D 30/014; H01L 23/5286; H10D 30/43; H10D 30/6729; H10D 30/6735; H10D 62/121; H10D 64/01; H10D 64/017; H10D 64/018

(57) ABSTRACT

A method for forming a semiconductor structure is provided. The method includes forming a fin structure over a substrate, forming an isolation structure surrounding a lower portion of the fin structure, forming a protection layer over the isolation structure, etching the fin structure, the protection layer and the isolation structure to form a first recess in the fin structure and a second recess in the isolation structure, forming a source/drain feature to fill the first recess, and forming an interlayer dielectric layer over the source/drain feature and filling the second recess.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIGS. 2A-1, 2A-2 and 2A-3 are cross-sectional views of the semiconductor structure corresponding to line Y1-Y1, line Y2-Y2 and line X-X of FIG. 1, in accordance with some embodiments of the disclosure.

FIGS. 2B-1, 2B-2 and 2B-3 are cross-sectional views of the semiconductor structure corresponding to line Y1-Y1, line Y2-Y2 and line X-X of FIG. 1, in accordance with some embodiments of the disclosure.

FIGS. 2C-1, 2C-2 and 2C-3 are cross-sectional views of the semiconductor structure corresponding to line Y1-Y1, line Y2-Y2 and line X-X of FIG. 1, in accordance with some embodiments of the disclosure.

FIGS. 2D-1, 2D-2 and 2D-3 are cross-sectional views of the semiconductor structure corresponding to line Y1-Y1, line Y2-Y2 and line X-X of FIG. 1, in accordance with some embodiments of the disclosure.

FIGS. 2E-1, 2E-2 and 2E-3 are cross-sectional views of the semiconductor structure corresponding to line Y1-Y1, line Y2-Y2 and line X-X of FIG. 1, in accordance with some embodiments of the disclosure.

FIGS. 2F-1, 2F-2 and 2F-3 are cross-sectional views of the semiconductor structure corresponding to line Y1-Y1, line Y2-Y2 and line X-X of FIG. 1, in accordance with some embodiments of the disclosure.

FIGS. 2G-1, 2G-2 and 2G-3 are cross-sectional views of the semiconductor structure corresponding to line Y1-Y1, line Y2-Y2 and line X-X of FIG. 1, in accordance with some embodiments of the disclosure.

FIGS. 2H-1, 2H-2 and 2H-3 are cross-sectional views of the semiconductor structure corresponding to line Y1-Y1, line Y2-Y2 and line X-X of FIG. 1, in accordance with some embodiments of the disclosure.

FIGS. 2I-1, 2I-2 and 2I-3 are cross-sectional views of the semiconductor structure corresponding to line Y1-Y1, line Y2-Y2 and line X-X of FIG. 1, in accordance with some embodiments of the disclosure.

FIGS. 2J-1, 2J-2 and 2J-3 are cross-sectional views of the semiconductor structure corresponding to line Y1-Y1, line Y2-Y2 and line X-X of FIG. 1, in accordance with some embodiments of the disclosure.

FIGS. 2K-1, 2K-2 and 2K-3 are cross-sectional views of the semiconductor structure corresponding to line Y1-Y1, line Y2-Y2 and line X-X of FIG. 1, in accordance with some embodiments of the disclosure.

FIGS. 2L-1, 2L-2 and 2L-3 are cross-sectional views of the semiconductor structure corresponding to line Y1-Y1, line Y2-Y2 and line X-X of FIG. 1, in accordance with some embodiments of the disclosure.

FIGS. 2M-1, 2M-2 and 2M-3 are cross-sectional views of the semiconductor structure corresponding to line Y1-Y1, line Y2-Y2 and line X-X of FIG. 1, in accordance with some embodiments of the disclosure.

FIGS. 2N-1, 2N-2 and 2N-3 are cross-sectional views of the semiconductor structure corresponding to line Y1-Y1, line Y2-Y2 and line X-X of FIG. 1, in accordance with some embodiments of the disclosure.

FIGS. 2C-4, 2D-4, 2F-4, 2G-4, 2L-4 and 2M-4 are plan views illustrating the formation of a semiconductor structure at various intermediate stages, in accordance with some embodiments of the disclosure.

FIGS. 3A-1, 3A-2 and 3A-3 are cross-sectional views of the semiconductor structure corresponding to line Y1-Y1, line Y2-Y2 and line X-X of FIG. 1, in accordance with some embodiments of the disclosure.

FIGS. 3B-1, 3B-2 and 3B-3 are cross-sectional views of the semiconductor structure corresponding to line Y1-Y1, line Y2-Y2 and line X-X of FIG. 1, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure and a method for forming the semiconductor structure are provided. The method includes forming an isolation structure surrounding a lower portion of a fin structure, and forming a protection layer over the isolation structure. During the etching process for forming a source/drain recess, the protection layer may reduce the damage of the etching to the isolation structure, thereby preventing the neighboring epitaxial material from merging with each other. In addition, During the etching process for forming a gate trench, the protection layer may protect the isolation structure from being damaged, thereby preventing the enlargement of a final gate stack. Therefore, the manufacturing yield and the performance of the resulting semiconductor device may improve.

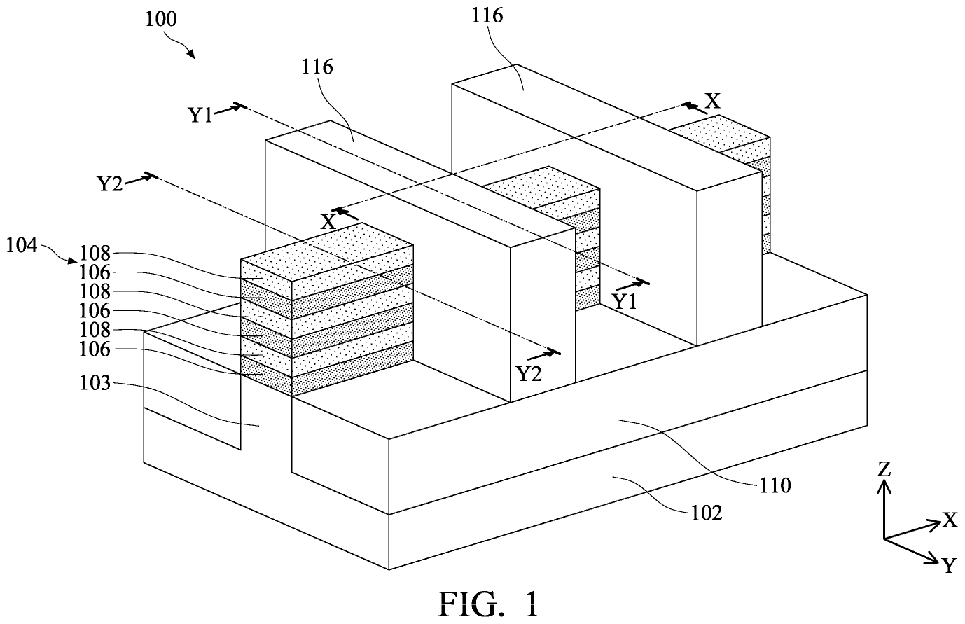

FIG. 1 is a perspective view of a semiconductor structure 100, in accordance with some embodiments. A semiconductor structure 100 is provided, as shown in FIG. 1, in accordance with some embodiments. The semiconductor structure 100 includes a substrate 102 and a fin structure 104 and an isolation structure 110 over the substrate 102, in accordance with some embodiments.

For a better understanding of the semiconductor structure, X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The fin structure 104 includes a lower fin element 104L surrounded by the isolation structure 110 and an upper fin element formed from an epitaxial stack including alternating first semiconductor layers 106 and second semiconductor layer 108, in accordance with some embodiments. The second semiconductor layers 108 will form nanostructures (e.g., nanowires or nanosheets) and serve as the channel for the resulting semiconductor devices, in accordance with some embodiments.

The fin structure 104 extends in the X direction, in accordance with some embodiments. That is, the fin structure 104 has a longitudinal axis parallel to the X direction, in accordance with some embodiments. The X direction may also be referred to as the channel-extending direction. The current of the resulting semiconductor device (i.e., nanostructure transistor) flows in the X direction through the channel. The fin structure 104 is defined as several channel regions and several source/drain regions, where the channel regions and the source/drain regions are alternately arranged, in accordance with some embodiments. In this disclosure, a source/drain refers to a source and/or a drain. It is noted that in the present disclosure, a source and a drain are interchangeably used and the structures thereof are substantially the same.

Gate structures 116 are formed with longitudinal axes parallel to the Y direction and extending across and/or surrounding the channel regions of the fin structure 104, in accordance with some embodiments. The source/drain regions of the fin structure 104 are exposed from the gate structures 116, in accordance with some embodiments. The Y direction may also be referred to as a gate-extending direction, in accordance with some embodiments.

FIG. 1 further illustrates reference cross-sections that are used in later figures. Cross-section Y1-Y1 is in a plan parallel to the longitudinal axis of the gate structure (i.e., Y direction) and across the channel region of the fin structure 104. Cross-section Y2-Y2 is in a plan parallel to the longitudinal axis of the gate structure (i.e., Y direction) and across the source/drain region of the fin structure 104. Cross-section X-X is in a plan parallel to the longitudinal axis of the fin structure 104 (i.e., X direction) and through the fin structure 104.

FIGS. 2A-1 through 2N-3 are schematic views illustrating the formation of a semiconductor structure 100 at various intermediate stages. FIGS. 2A-1, 2A-2 and 2A-3 are cross-sectional views of the semiconductor structure 100 after the formation of an active region 104, a semiconductor capping layer 109, an isolation structure 110 and a dielectric layer 112 corresponding to line Y1-Y1, line Y2-Y2 and line X-X of FIG. 1, in accordance with some embodiments of the disclosure.

The semiconductor structure 100 includes a substrate 102 and an active region 104 over the substrate 102, as shown in FIGS. 2A-1 to 2A-3, in accordance with some embodiments. In some embodiments, the semiconductor structure 100 is used to form nanostructure transistors with a backside power rail architecture. Backside power rail architecture may reduce the overall resistance of the BEOL (backend of lines) metal layers, and/or the complexity of the metal routing on the frontside of the substrate may be reduced, which may facilitate the continued scaling of semiconductor devices. The frontside of the semiconductor structure 100 faces upward, in accordance with some embodiments.

The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GalnP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

In some embodiments, the active region 104 extends in the X direction. The active region 104 has a longitudinal axis parallel to the X direction, in accordance with some embodiments. In some embodiments, the active region 104 is the fin structure 104 shown in FIG. 1. Although one active region 104 is shown in FIG. 1, the number of the active region 104 is not limited thereto, and may depend on the performance and design demands of the resulting semiconductor device.

The formation of the active region 104 includes forming an epitaxial stack over the substrate 102 using an epitaxial growth process, in accordance with some embodiments. The epitaxial stack may be formed by depositing a first semiconductor layer 106 on the substrate 102, depositing a second semiconductor layers 108 on the first semiconductor layer 106, and repeating the cycle of depositing the semiconductor layers 106 and 108 several times. The first semiconductor layers 106 and the second semiconductor layers 108 are alternately stacked vertically, in accordance with some embodiments. The epitaxial growth process may be molecular beam epitaxy (MBE), metal organic chemical vapor deposition (MOCVD), vapor phase epitaxy (VPE), or another suitable technique.

In some embodiments, the first semiconductor layers 106 are made of a first semiconductor material and the second semiconductor layers 108 are made of a second semiconductor material with a different composition than the first semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, in accordance with some embodiments. The second semiconductor layers 108 will form nanostructures (e.g., nanowires or nanosheets) that laterally extend between source/drain features and serve as the channel for the resulting semiconductor device (such as a nanostructure transistor), in accordance with some embodiments. As the term is used herein, “nanostructures” refers to semiconductor layers that have cylindrical shape, bar shape and/or sheet shape. A gate stack (not shown) will be formed across and wrap around the nanostructures, in accordance with some embodiments. Although four first semiconductor layers 106 and four second semiconductor layers 108 are shown in FIGS. 2A-1 to 2A-3, the number is not limited to four, and can be two, three or five, and is less than ten.

In some embodiments, the bottommost second semiconductor layer 108_1 is thicker than the other second semiconductor layers 108. In some embodiments, the thickness T1 of the bottommost second semiconductor layer 108_1 is in a range from about 5 nm to about 30 nm. In some embodiments, the thickness T2 of the other second semiconductor layers 108 is in a range from about 3 nm to about 20 nm, such as about 4 nm to about 12 nm. In some embodiments, the thickness of each of the first semiconductor layers 106 is in a range from about 3 nm to about 20 nm, such as about 4 nm to about 12 nm.

The formation of the active region 104 further includes patterning the epitaxial stack and the underlying substrate 102 using photolithography and etching processes, thereby forming trenches and the active region 104 protruding from between trenches, in accordance with some embodiments. The portion of the substrate 102 protruding from between the trenches serves as a lower fin element 104L of the active region 104, in accordance with some embodiments. The remainder of the epitaxial stack (including the first semiconductor layers 106 and the second semiconductor layers 108) serves as the upper fin element of the active region 104, in accordance with some embodiments.

A semiconductor capping layer 109 is formed on the exposed surface of the active region 104 and the substrate 102 using an epitaxial growth process, as shown in FIGS. 2A-1 to 2A-3, in accordance with some embodiments. In some embodiments, the semiconductor capping layer 109 is made of semiconductor material such as silicon. The epitaxial growth process may be MBE, MOCVD, or VPE, another suitable technique, or a combination thereof.

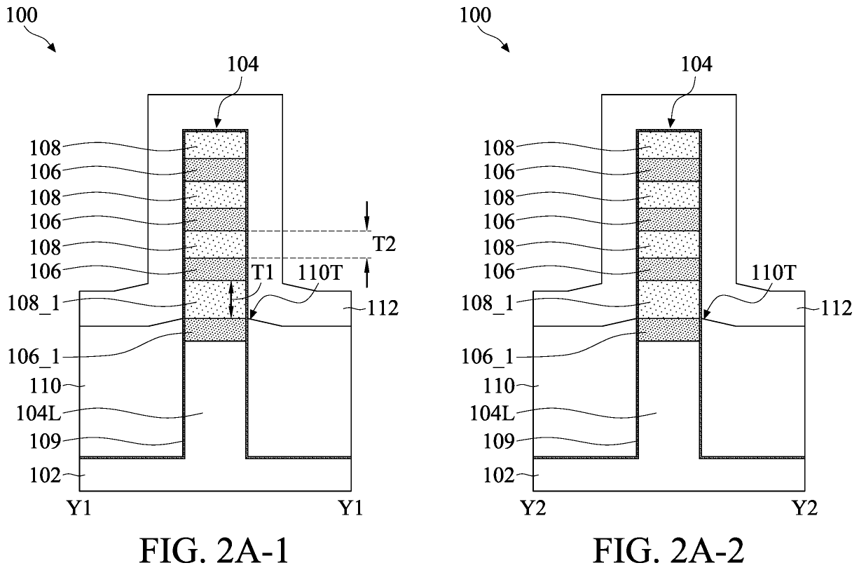

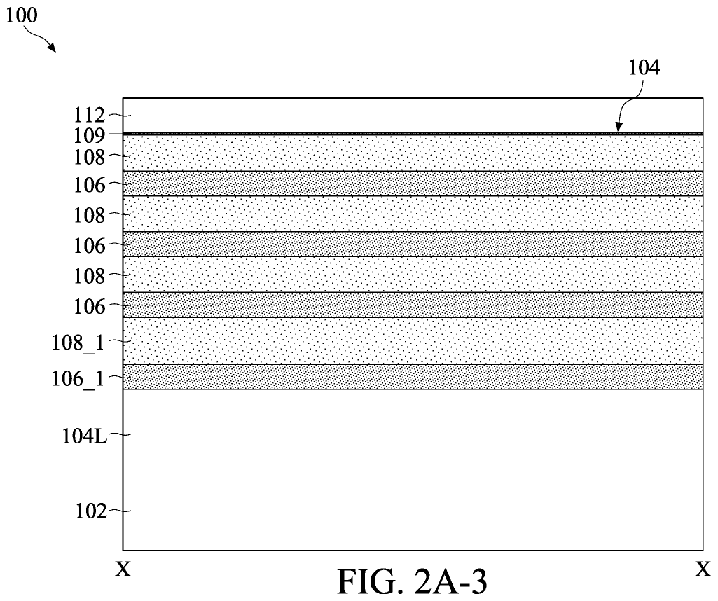

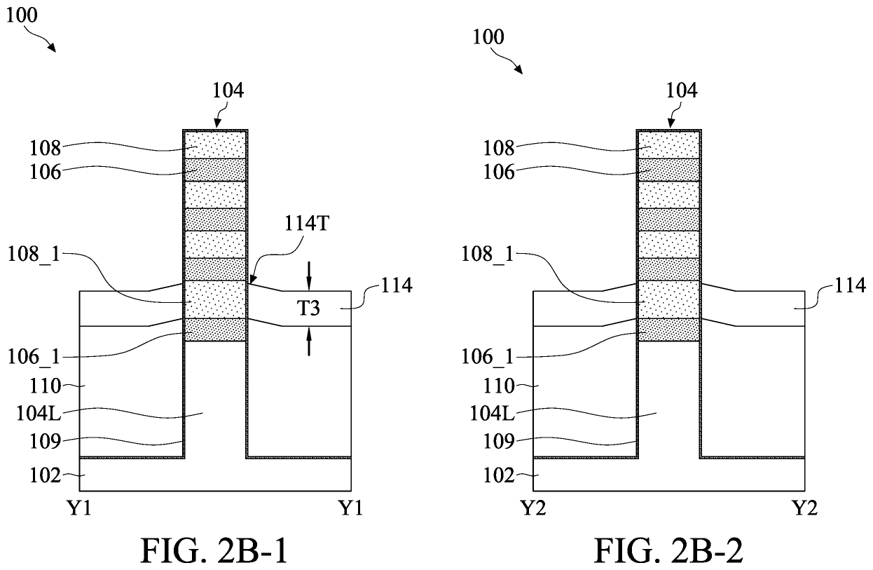

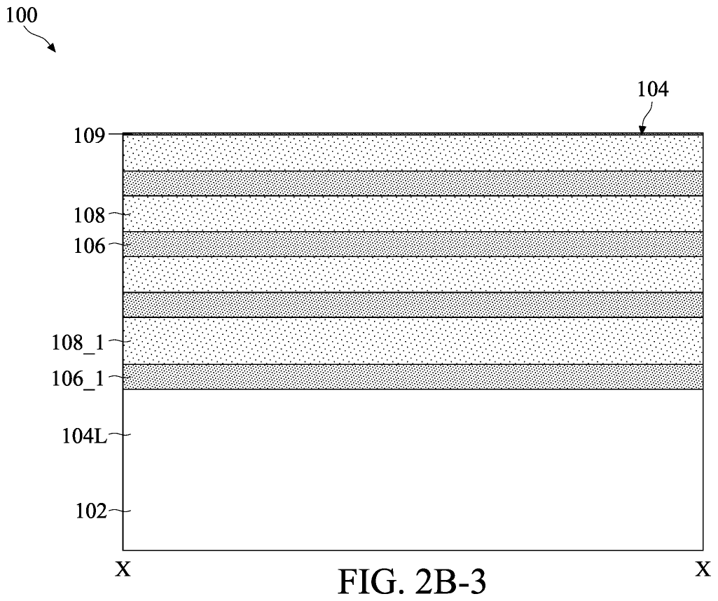

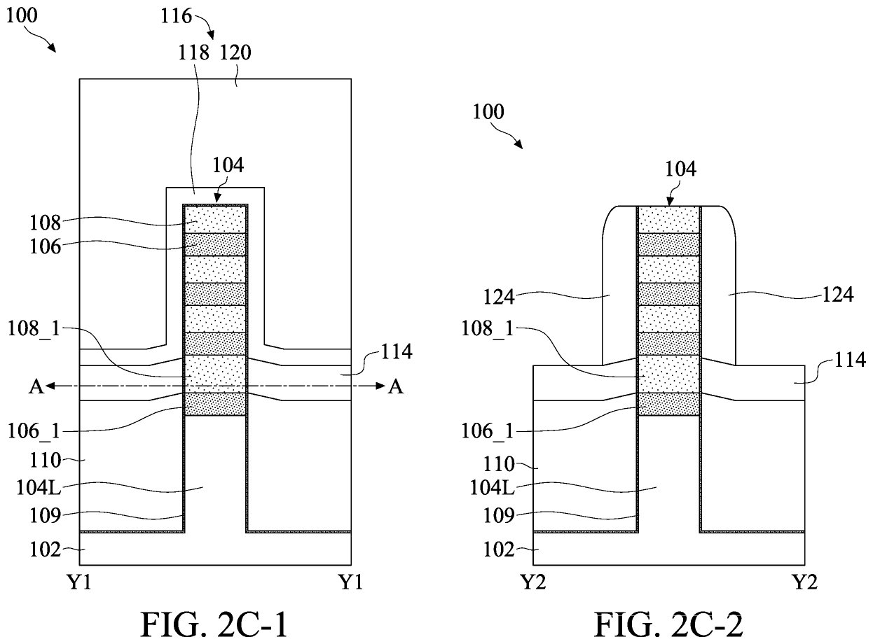

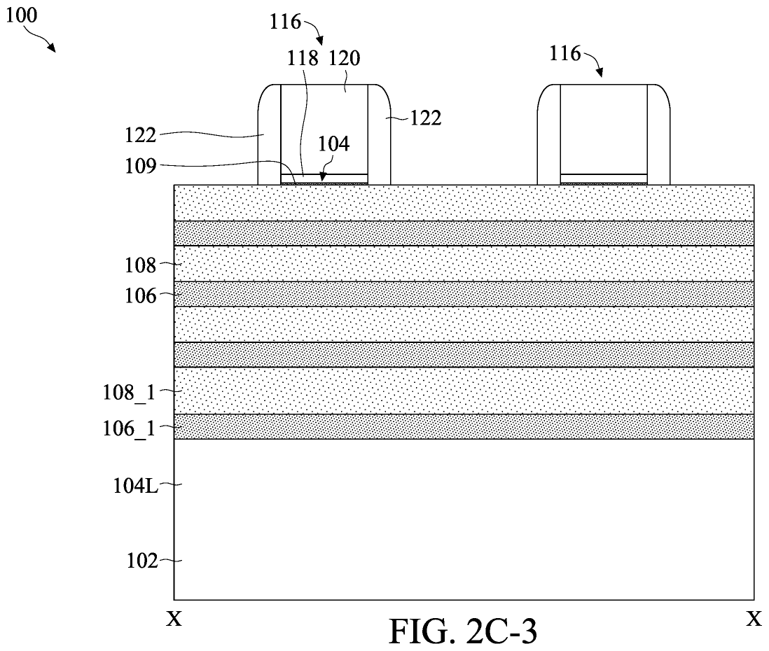

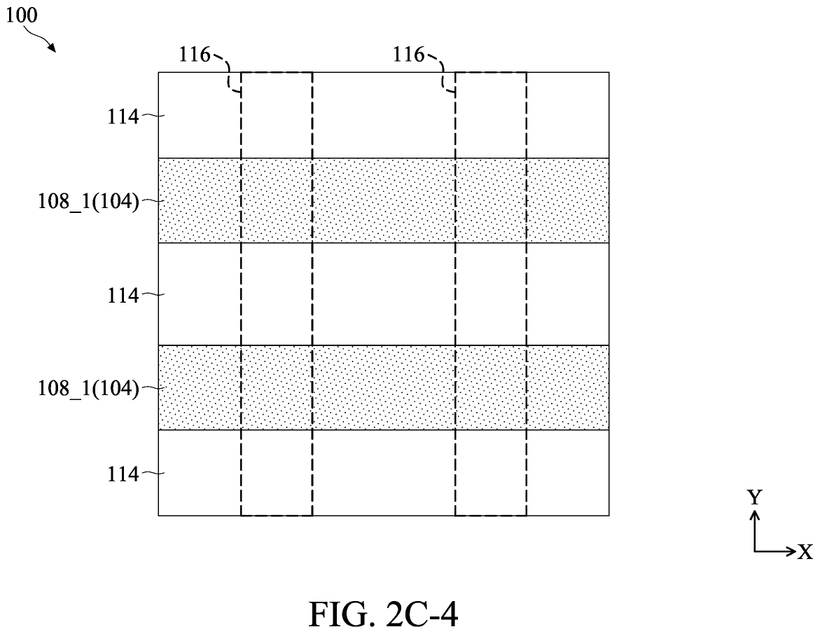

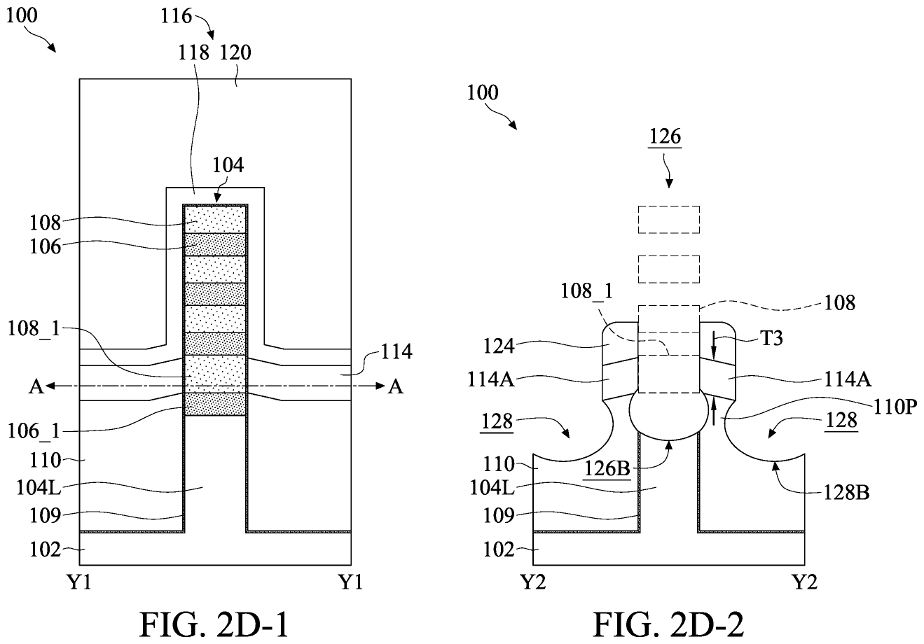

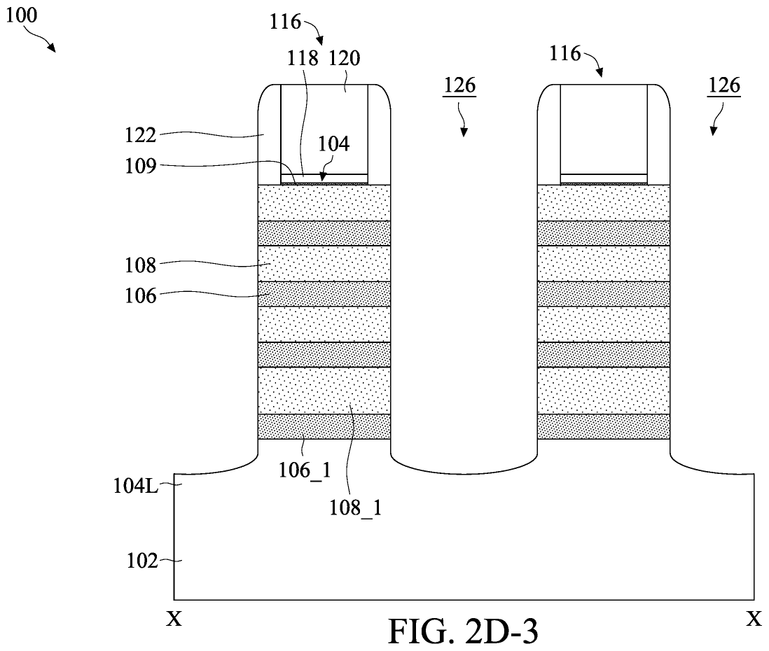

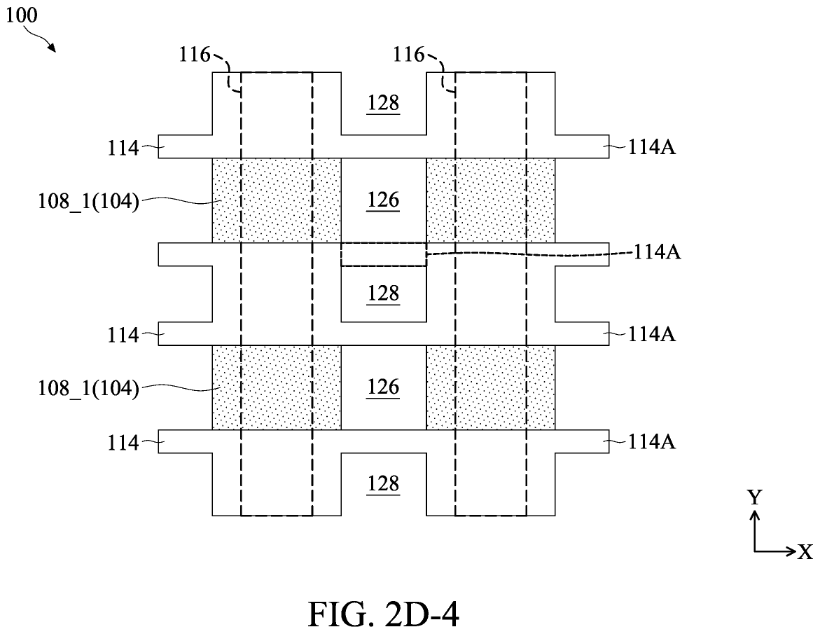

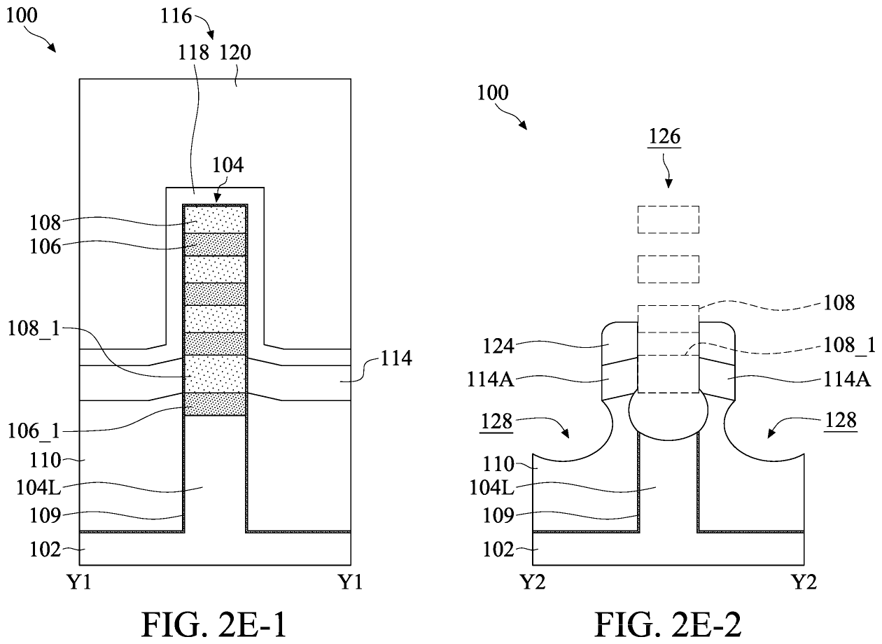

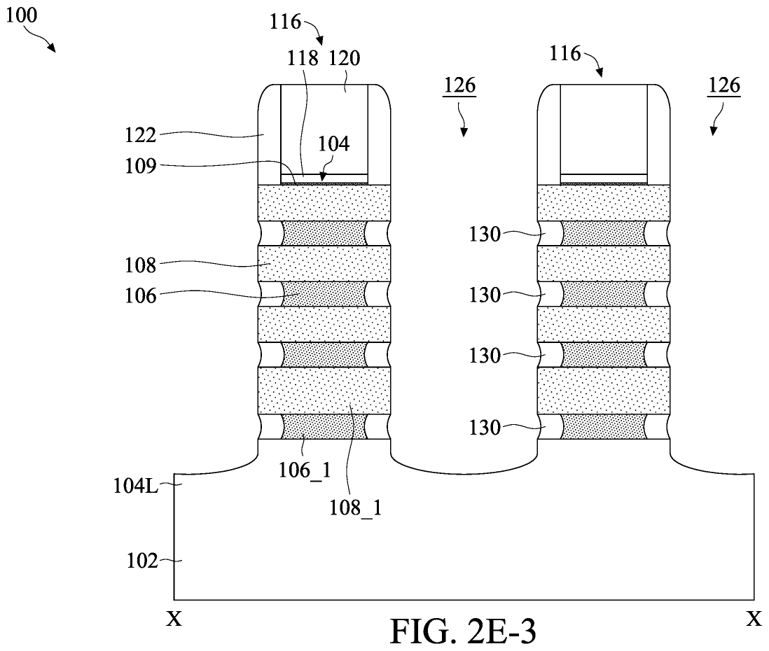

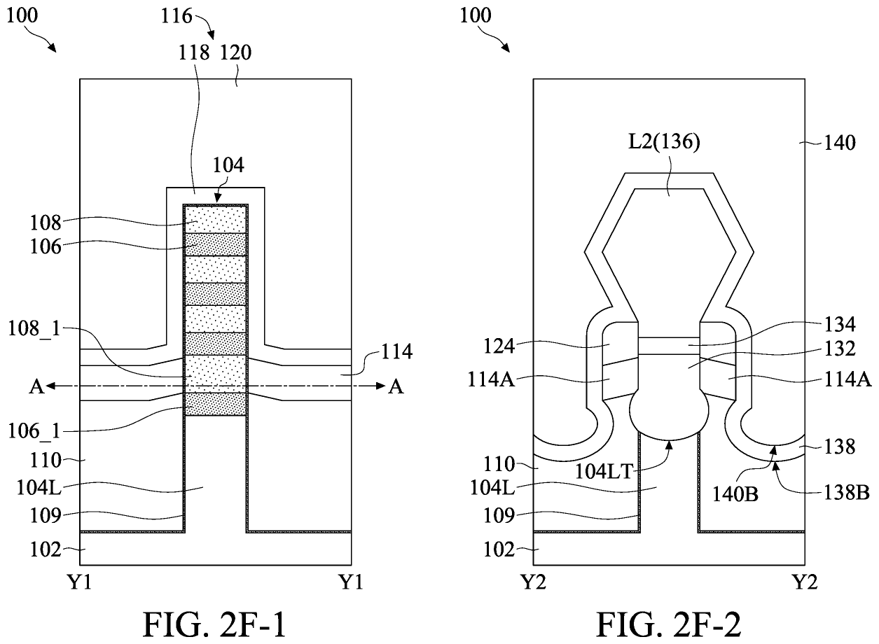

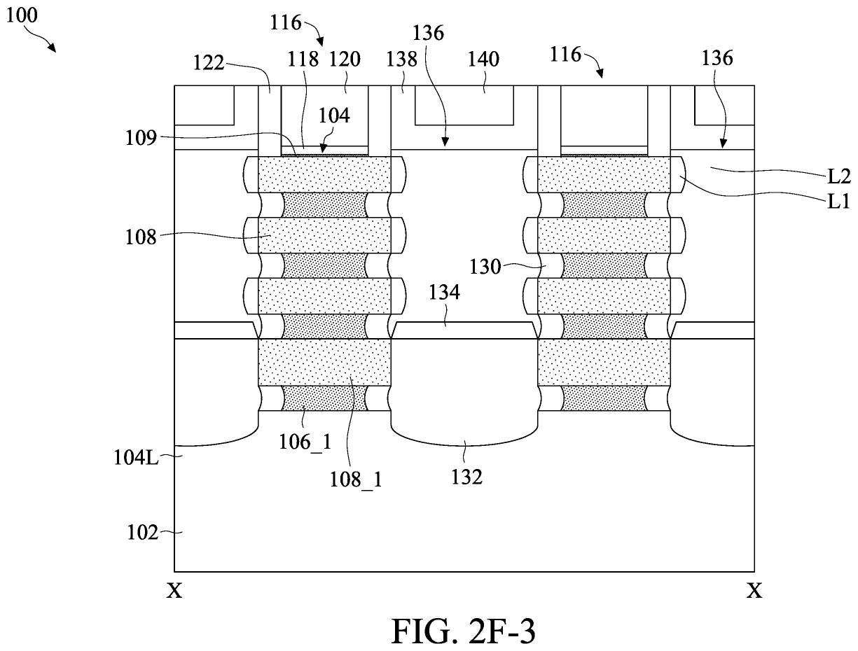

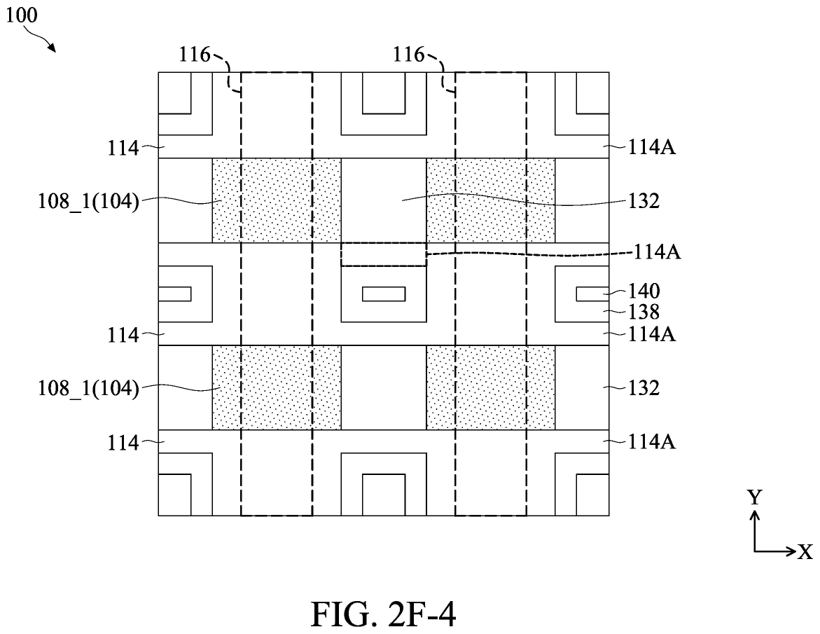

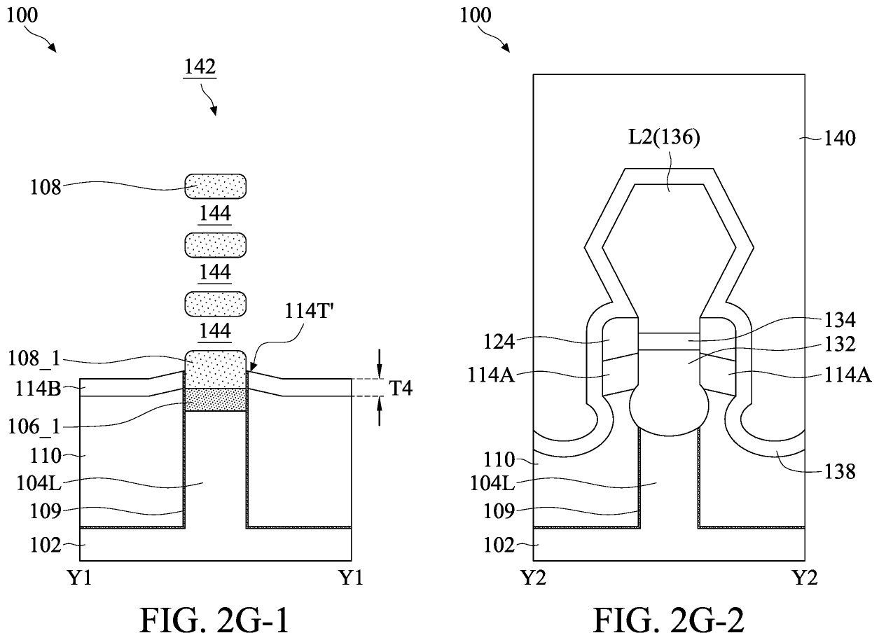

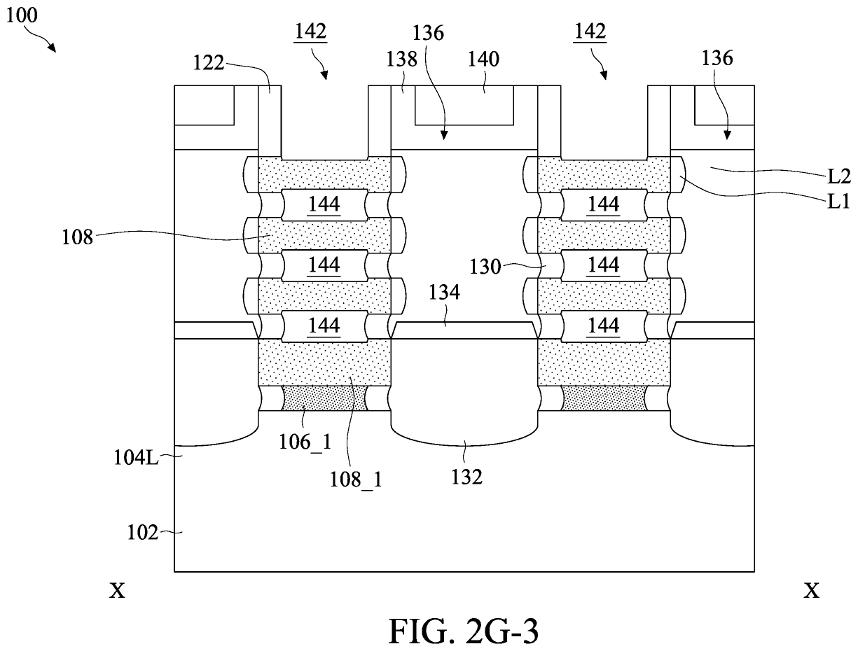

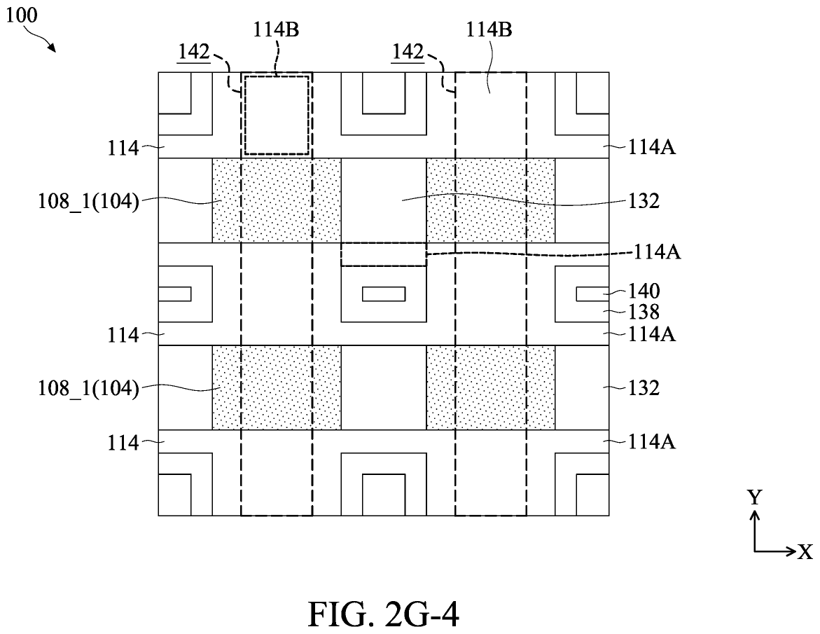

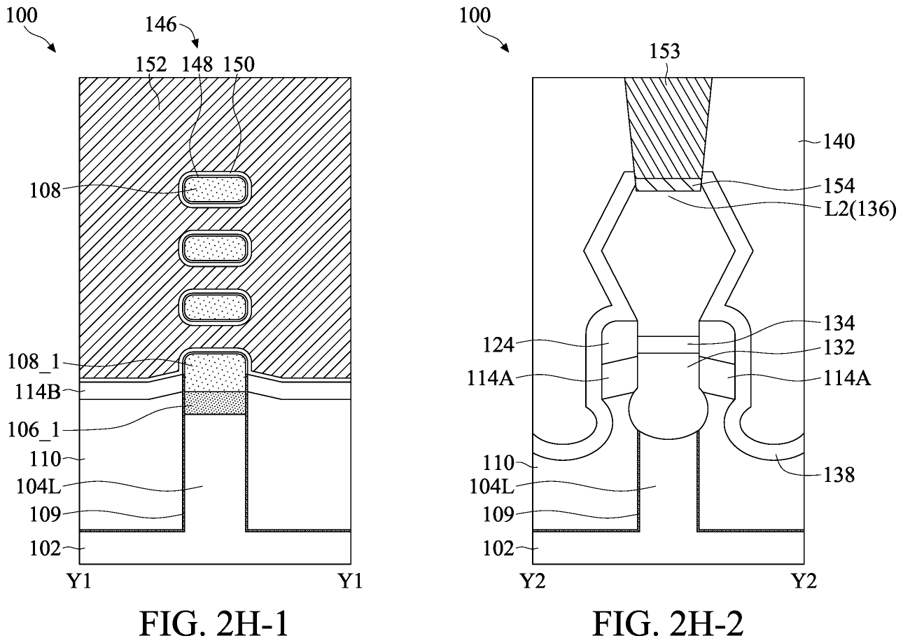

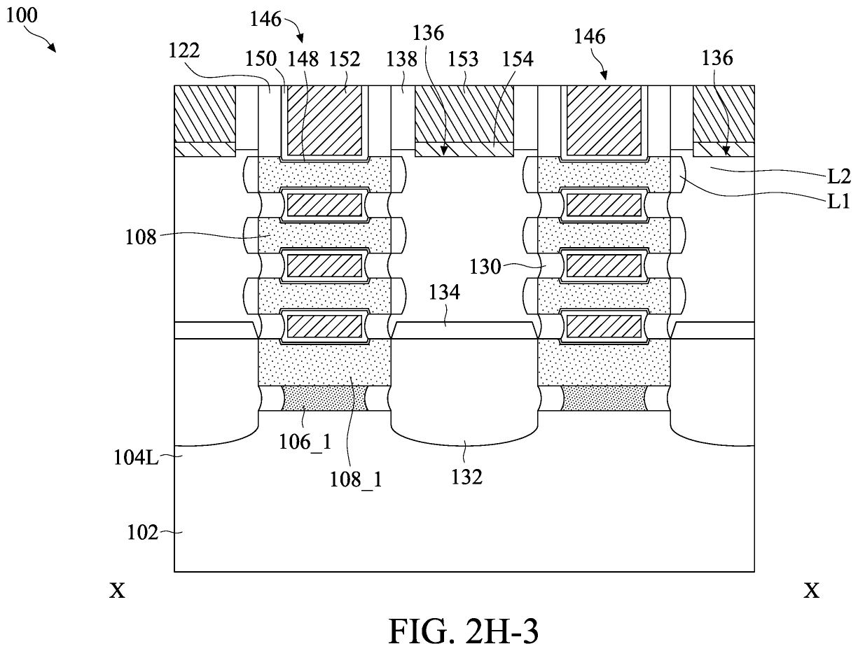

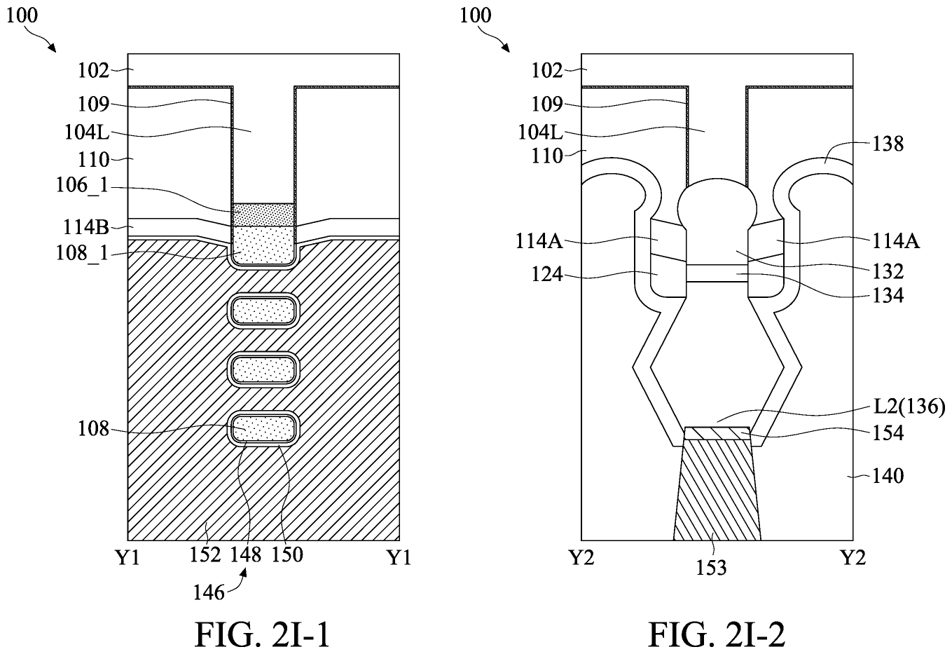

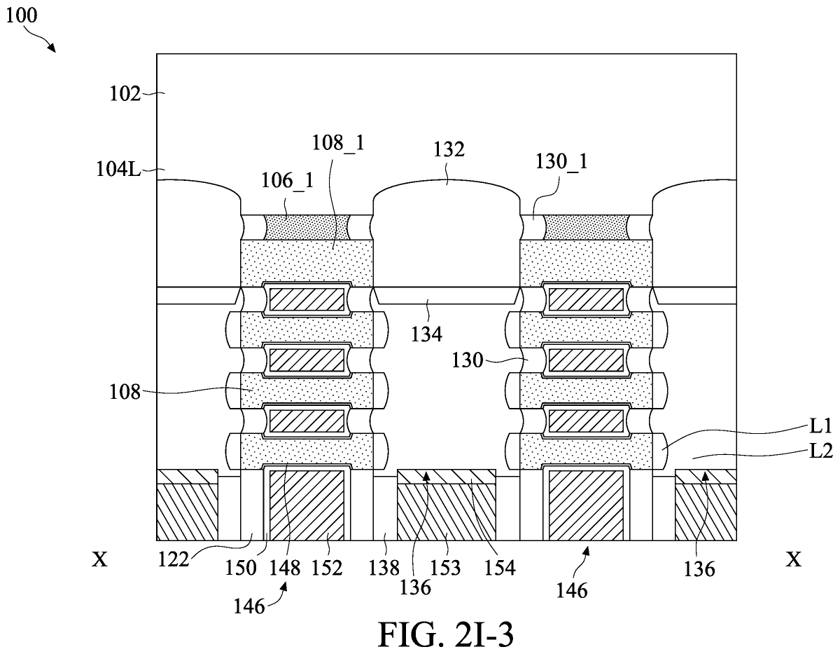

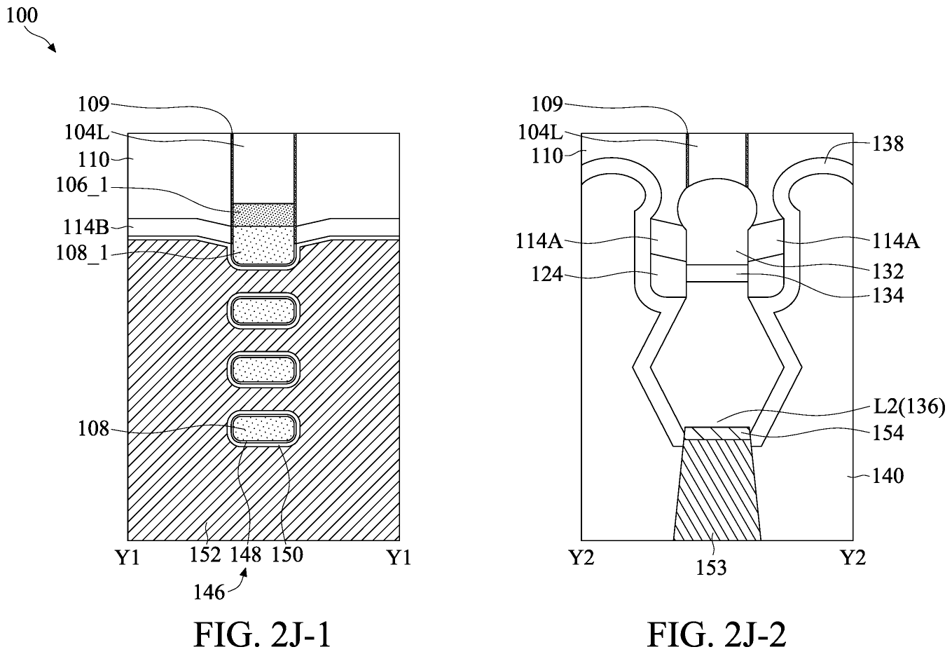

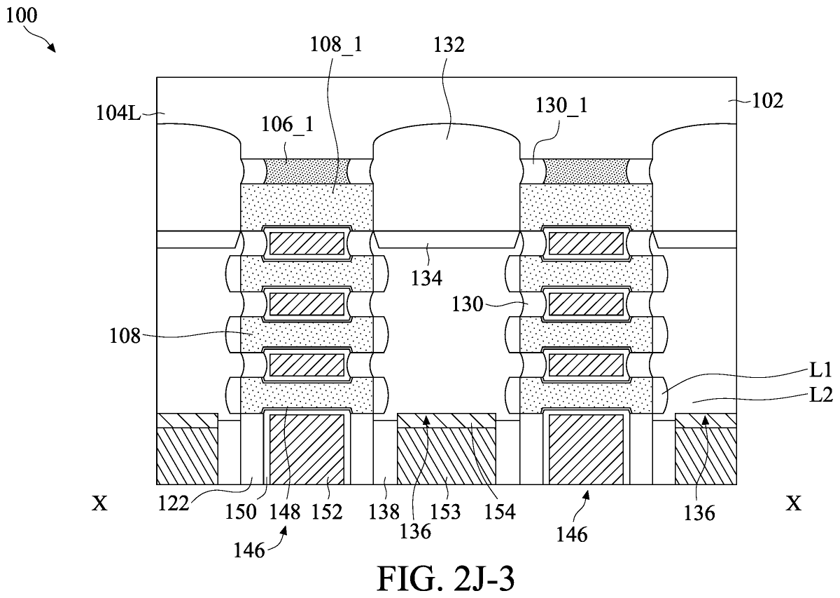

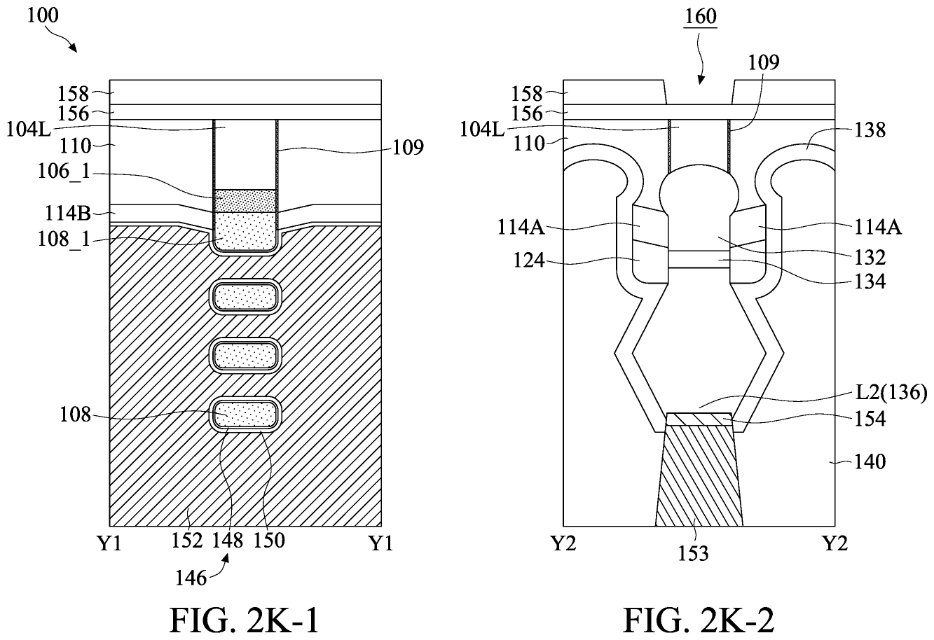

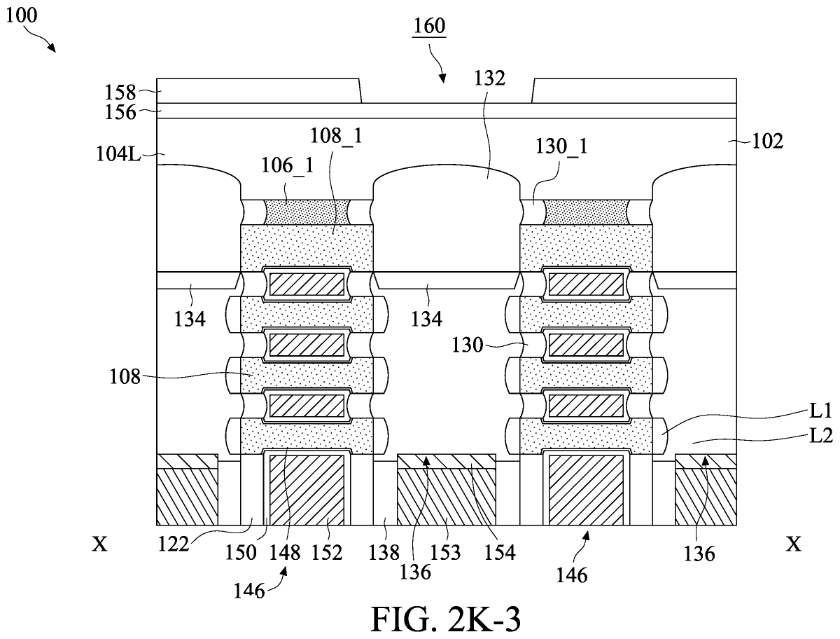

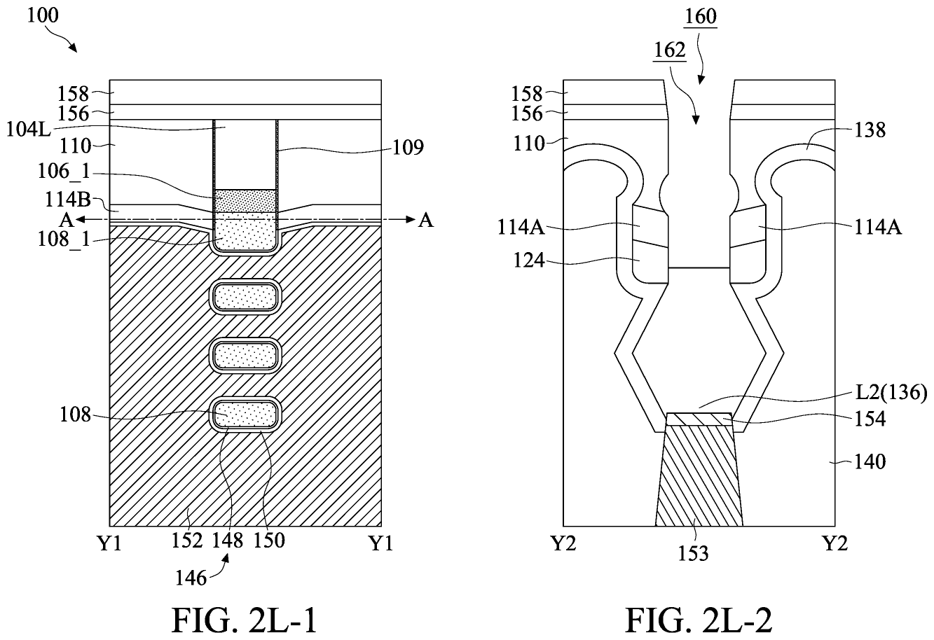

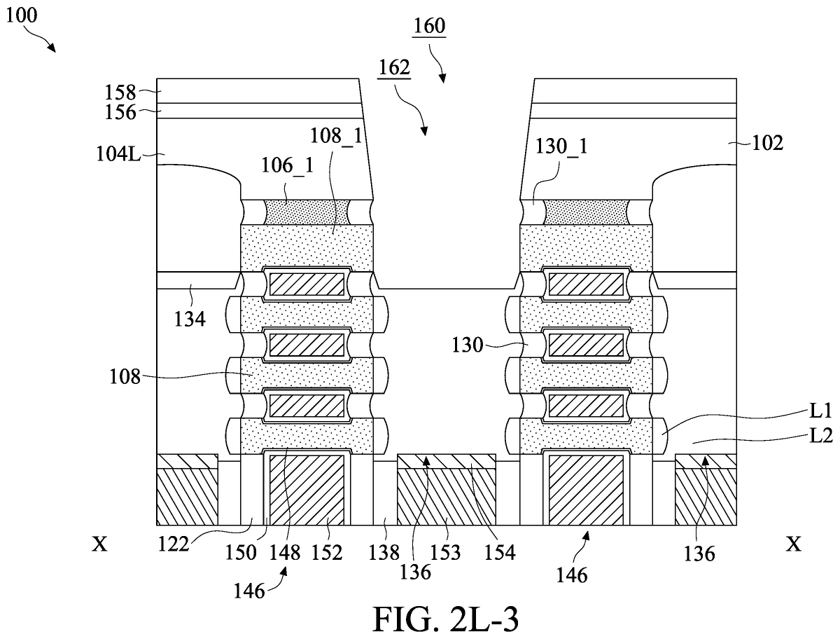

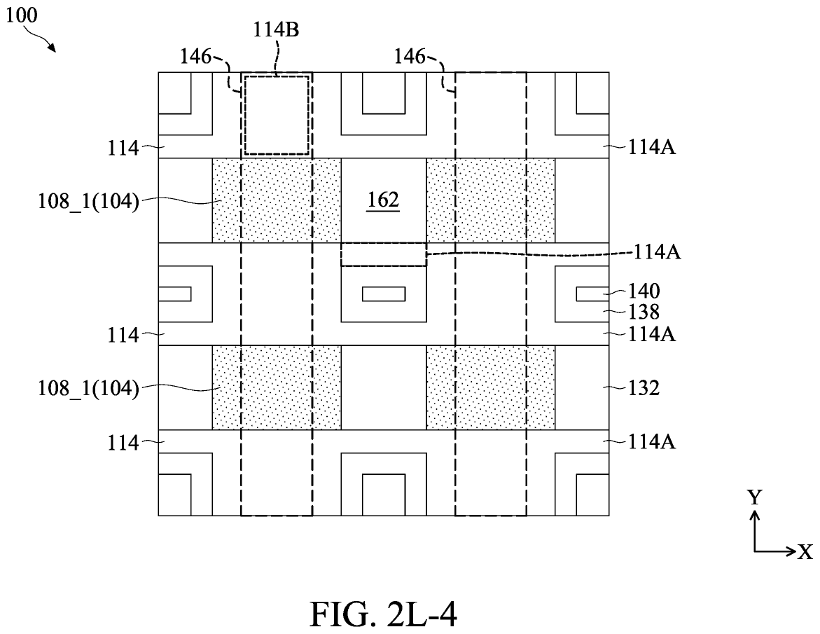

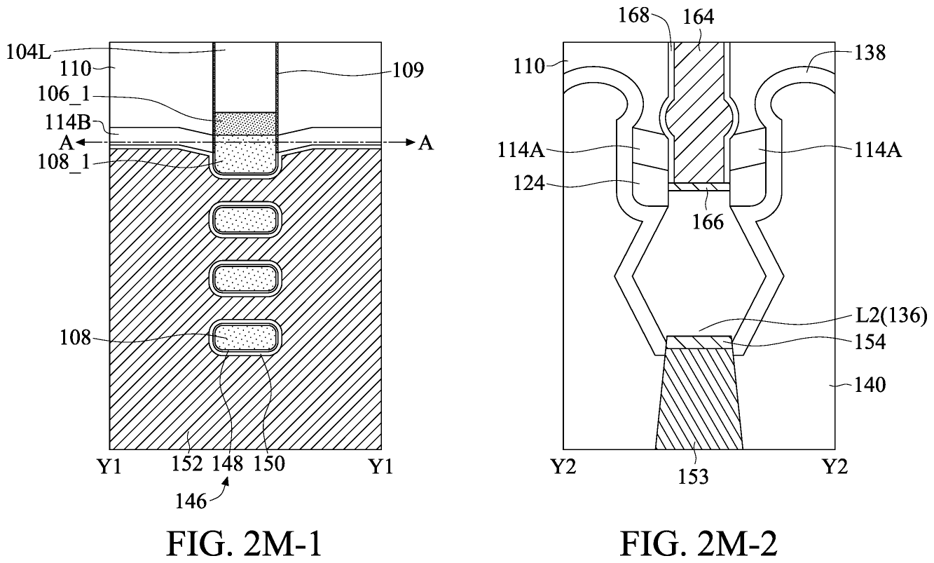

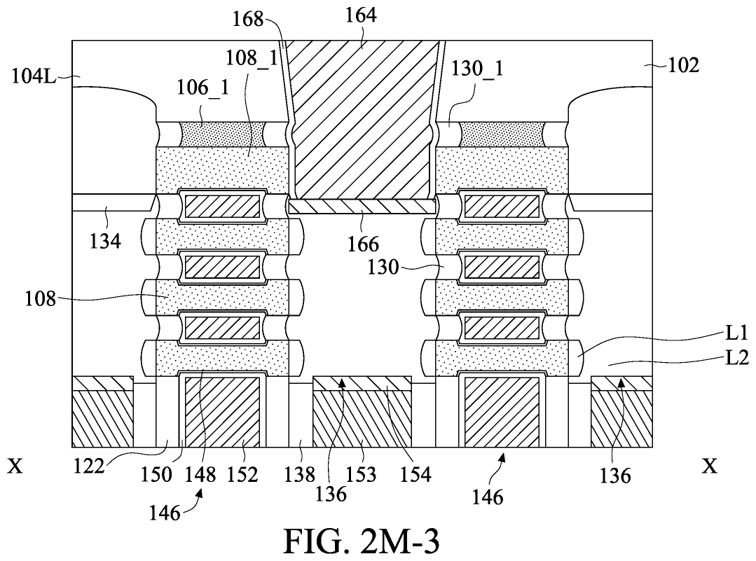

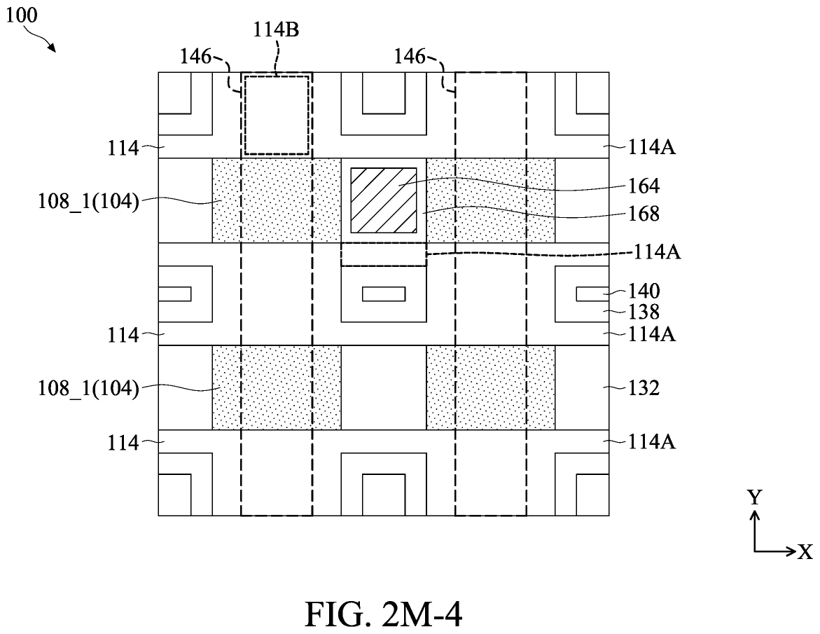

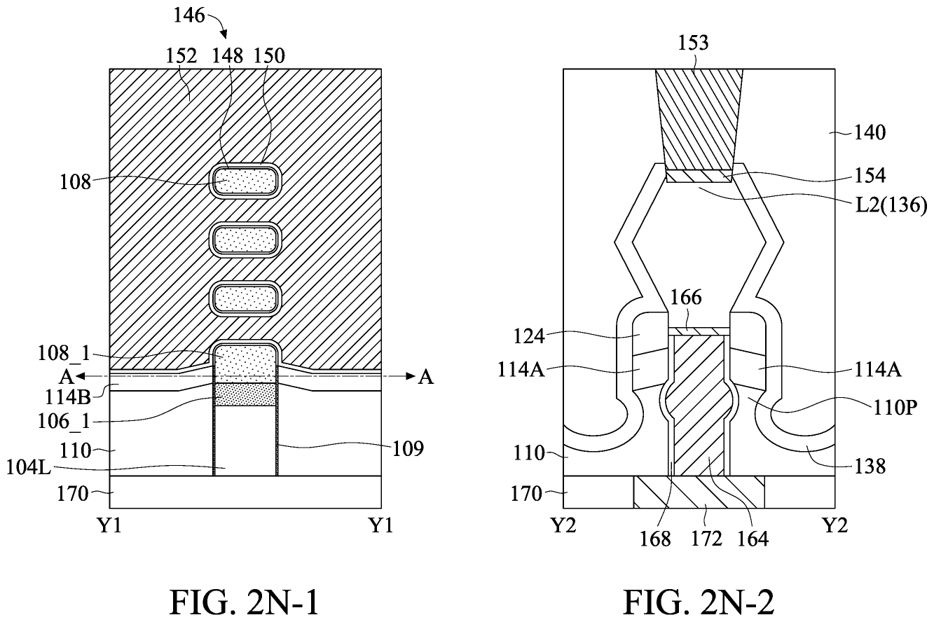

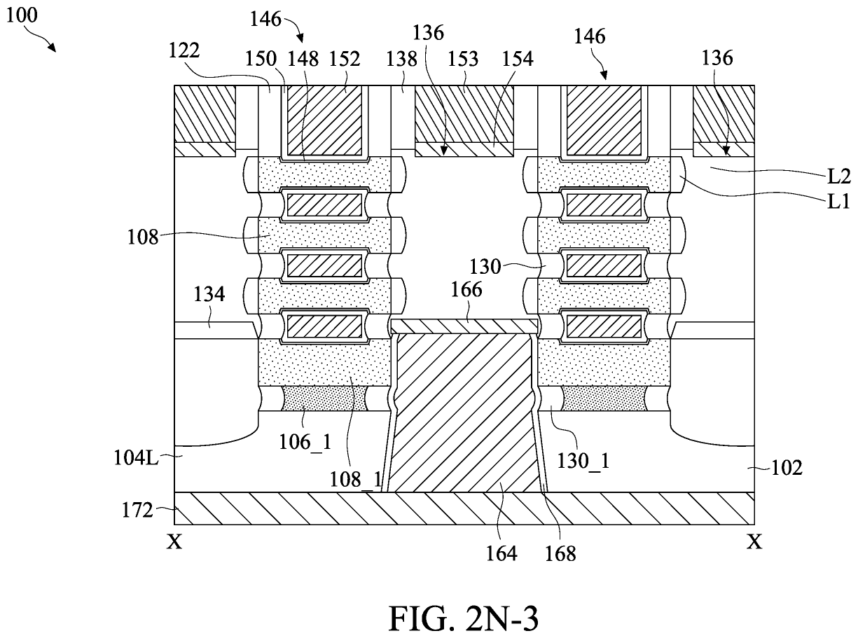

An isolation structure 110 is formed to surround the lower fin element 104L of the active region 104, as shown in FIGS. 2A-1 and 2A-2, in accordance with some embodiments. The isolation structure 110 further surrounds the bottommost first semiconductor layer 106_1, in accordance with some embodiments. The isolation structure 110 is configured to electrically isolate neighboring active regions 104 and is also referred to as shallow trench isolation (STI) feature, in accordance with some embodiments.

In some embodiments, the top 110T of the isolation structure 110 may be located at the boundaries between the isolation structure 110 and the semiconductor capping layer 109 due to the characteristic of the etching process. In some embodiments, the top 110T of the isolation structure 110 is located at a position between the bottom surface and the top surface of the bottommost first semiconductor layer 106_1.

The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active region 104, in accordance with some embodiments. The planarization may be chemical mechanical polishing (CMP), an etching back process, or a combination thereof. The insulating material is then recessed by an etching process (such as dry plasma etching and/or wet chemical etching) to expose the sidewalls of the upper fin element of the active region 104, in accordance with some embodiments. The remaining insulating material serves as the isolation structure 110, in accordance with some embodiments.

A dielectric layer 112 is formed along the sidewalls and the top surface of the upper fin element of the active region 104 and the top surface of the isolation structure 110, as shown in FIGS. 2A-1 to 2A-3, in accordance with some embodiments. In some embodiments, the dielectric layer 112 and the isolation structure 110 are made of different materials and have a great difference in etching selectivity.

In some embodiments, the dielectric layer 112 is a dielectric material such as silicon oxide (SiO₂), silicon oxynitride (SiON), silicon nitride (SiN), silicon carbon nitride (SiCN), silicon oxycarbonitride (SiOCN), oxygen-doped silicon carbonitride (Si(O)CN), SiBCN, or a combination thereof. In some embodiments, the insulating strips 134 include dielectric material with k-value greater than 7.9, such as LaO, AlO, AlON, ZrO, HfO, ZnO, ZrN, ZrAlO, TiO, TaO, YO, TaCN, or a combination thereof.

FIGS. 2B-1, 2B-2 and 2B-3 are cross-sectional views of the semiconductor structure 100 after an etching process corresponding to line Y1-Y1, line Y2-Y2 and line X-X of FIG. 1, in accordance with some embodiments of the disclosure.

An etching process is performed on the dielectric layer 112 to remove the portion of the dielectric layer 112 along the sidewalls and the top surface of the upper fin element of the active region 104 until the semiconductor capping layer 109 is exposed, as shown in FIGS. 2B-1 to 2B-3, in accordance with some embodiments. The etching process may be an anisotropic etching process such as dry plasma etching, an isotropic etching process such as dry chemical etching, remote plasma etching or wet chemical etching, or a combination thereof.

The portion of the dielectric layer 112 along the top surface of the isolation structure 110 forms a protection layer 114, which may protect the isolation structure 110 from being damaged in the following etching processes, in accordance with some embodiments. The bottommost second semiconductor layer 108_1 is surrounded by the protection layer 114, in accordance with some embodiments.

In some embodiments, the top 114T of the protection layer 114 may be located at the boundaries between the protection layer 114 and the semiconductor capping layer 109 due to the characteristic of the etching process. In some embodiments, the top 114T of the protection layer 114 is located at a position between the bottom surface and the top surface of the bottommost second semiconductor layer 108_1. In some embodiments, the sidewalls of the bottommost first semiconductor layer 106_1 are covered by the isolation structure 110 and/or the protection layer 114, and not exposed.

FIGS. 2C-1, 2C-2 and 2C-3 are cross-sectional views of the semiconductor structure 100 after the formation of dummy gate structures 116, the gate spacer layers 122 and the fin spacer layers 124 corresponding to line Y1-Y1, line Y2-Y2 and line X-X of FIG. 1, in accordance with some embodiments of the disclosure. FIG. 2C-4 is a plan view of the semiconductor structure 100 taken along plan A-A in FIG. 2C-1.

Dummy gate structures 116 are formed across the active region 104 and the protection layer 114, as shown in FIGS. 2C-1, 2C-3 and 2C-4, in accordance with some embodiments. The dummy gate structures 116 are configured as sacrificial structures and will be replaced with the final gate stacks, in accordance with some embodiments. In some embodiments, the dummy gate structures 116 extend in the Y direction. That is, the dummy gate structures 116 have longitudinal axes parallel to the Y direction, in accordance with some embodiments. The dummy gate structures 116 surround the channel regions of the active region 104, in accordance with some embodiments. The dummy gate structures 116 may be the gate structures 116 shown in FIG. 1.

Each of the dummy gate structures 116 includes a dummy gate dielectric layer 118 and a dummy gate electrode layer 120 formed over the dummy gate dielectric layer 118, as shown in FIGS. 2C-1 and 2C-3, in accordance with some embodiments. In some embodiments, the dummy gate dielectric layer 118 is conformally formed along the upper fin element of the active region 104. In some embodiments, the dummy gate dielectric layer 118 is made of one or more dielectric materials, such as silicon oxide (SiO), silicon nitride (SiN), silicon oxynitride (SiON), HfO₂, HfZrO, HfSiO, HfTiO, HAIO. In some embodiments, the dielectric material is deposited using ALD, CVD, thermal oxidation, physical vapor deposition (PVD), another suitable technique, or a combination thereof.

In some embodiments, the dummy gate electrode layer 120 is made of semiconductor material such as polysilicon or poly-silicon germanium. In some embodiments, the material for the dummy gate electrode layer 120 is deposited using CVD, ALD, another suitable technique, or a combination thereof.

In some embodiments, the formation of the dummy gate structures 116 includes globally and conformally depositing a dielectric material for the dummy gate dielectric layer 118 over the semiconductor structure 100, depositing a material for the dummy gate electrode layer 120 over the dielectric material, planarizing the material for the dummy gate electrode layer 120, and patterning the material for the dummy gate electrode layer 120 and the dielectric material into the dummy gate structures 116.

The patterning process includes forming a patterned hard mask layer (not shown) over the material for the dummy gate electrode layer 120, in accordance with some embodiments. The patterned hard mask layer corresponds to and overlaps the channel regions of the active region 104, in accordance with some embodiments. The materials for the dummy gate dielectric layer 118 and the dummy gate electrode layer 120, uncovered by the patterned hard mask layer, are etched away until the active region 104 and the top surface of the protection layer 114 are exposed, in accordance with some embodiments. In the etching process, the semiconductor capping layer 109 is also removed, in accordance with some embodiments.

In the etching process for forming the dummy gate structures 116, the protection layer 114 may protect the isolation structure 110 from being damaged, in accordance with some embodiments. In some instances where the portion of the dummy gate structure 116 over the isolation structure 110 may have a footing profile (e.g., tapered sidewalls), if the isolation structure is recessed, a subsequently formed final gate stack may be too close to a subsequently formed backside contact plug in a diagonal direction (sandwiched between the X and Y directions), thereby increasing the risk of leakage between the final gate stack and the backside contact plug. Therefore, the formation of the protection layer 114 may prevent the subsequently formed final gate stack from being too close to the subsequently formed backside contact plug in the diagonal direction. The risk of leakage between the final gate stack from and the backside contact plug may reduce.

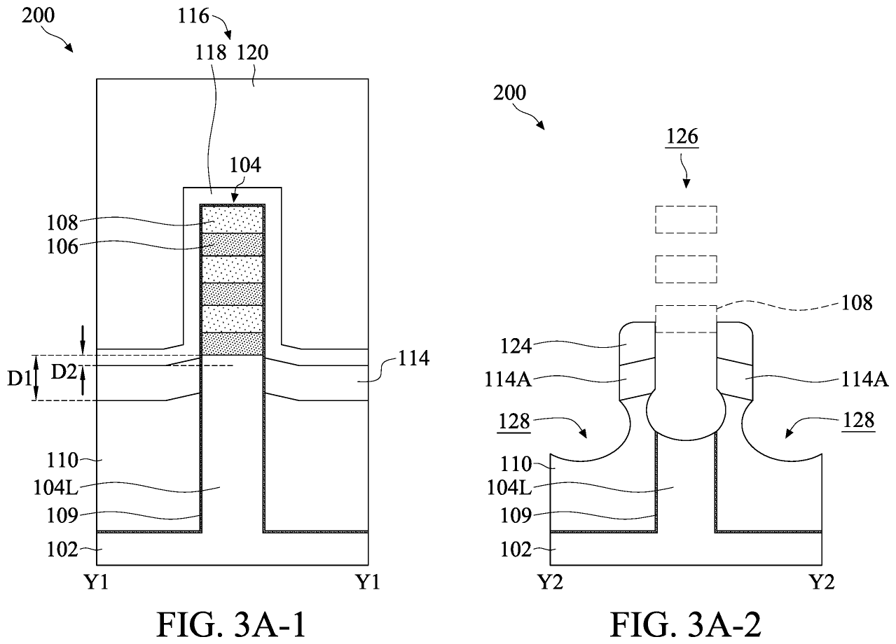

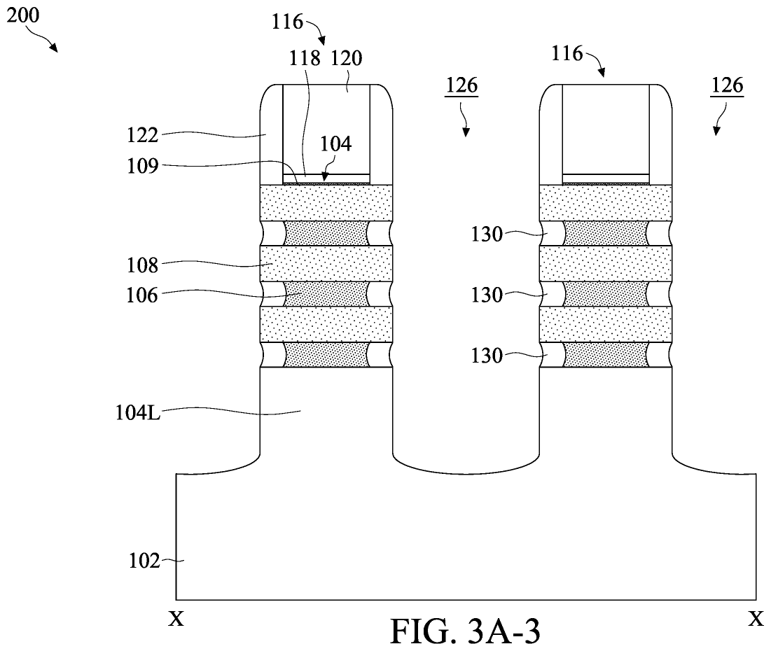

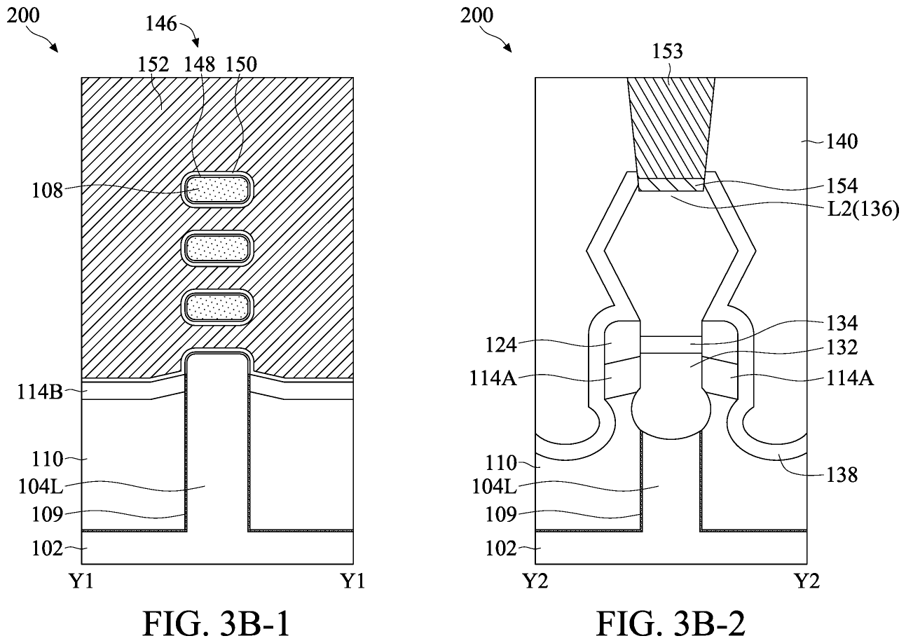

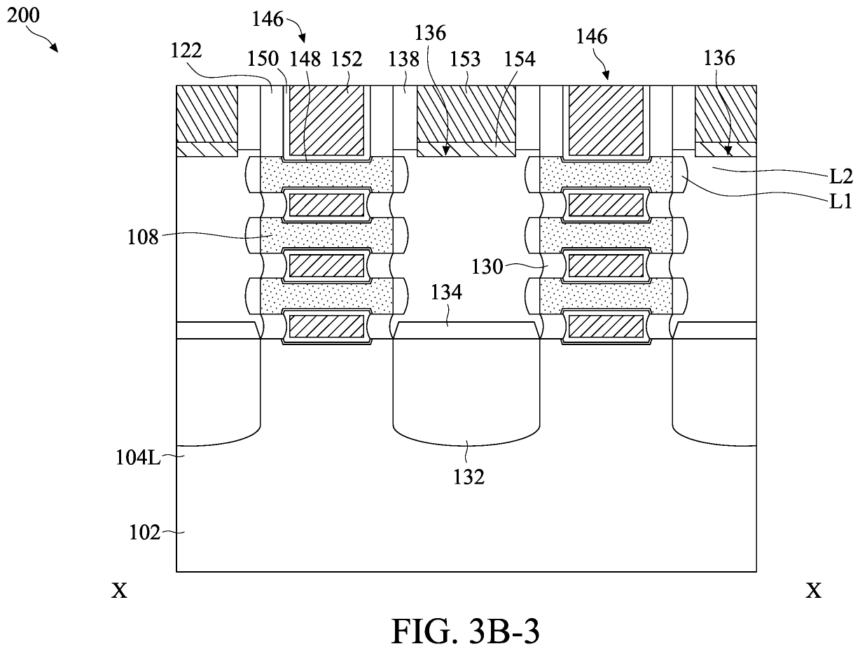

Gate spacer layers 122 are formed along opposite sidewalls of the dummy gate structures 112, and fin spacer layers 124 are formed along opposite sidewalls of the active region 104, as shown in FIGS. 2C-2 and 2C-3, in accordance with some embodiments. The gate spacer layers 122 extend in the Y direction and across the active regions 104 and the protection layer 114, in accordance with some embodiments. The gate spacer layers 122 are used to offset the subsequently formed source/drain features and separate the source/drain features from the gate structure, in accordance with some embodiments.

The fin spacer layers 124 extend in the X direction, in accordance with some embodiments. The fin spacer layers 124 are used to confine the growth of epitaxial material to prevent neighboring epitaxial material from merging with each other, in accordance with some embodiments.

In some embodiments, the gate spacer layers 122 and the fin spacer layers 124 are formed from a continuous dielectric material. In some embodiments, the formation of the gate spacer layers 122 and the fin spacer layers 124 includes globally and conformally depositing a dielectric material over the semiconductor structure 100 using atomic layer deposition (ALD), CVD (such as LPCVD, PECVD, HDP-CVD and HARP), another suitable method, and/or a combination thereof, followed by an anisotropic etching process. In some embodiments, the etching process is performed without an additional photolithography process. In some embodiments, the gate spacer layers 122 and the fin spacer layers 124 may be silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof.

The vertical portions of the dielectric material left remaining on the opposite sides of the dummy gate structure 116 serve as the gate spacer layers 124, in accordance with some embodiments. The vertical portions of the dielectric material left remaining on the opposite sides of the active region 104 serve as fin spacer layers 126, in accordance with some embodiments.

FIGS. 2D-1, 2D-2 and 2D-3 are cross-sectional views of the semiconductor structure 100 after an etching process corresponding to line Y1-Y1, line Y2-Y2 and line X-X of FIG. 1, in accordance with some embodiments of the disclosure. FIG. 2D-4 is a plan view of the semiconductor structure 100 taken along plan A-A in FIG. 2D-1.

An etching process is performed to recess the source/drain regions of the active region 104, thereby forming source/drain recesses 126, as shown in FIGS. 2D-2 to 2D-4, in accordance with some embodiments. The etching process may be an anisotropic etching process such as dry plasma etching, an isotropic etching process such as dry chemical etching, remote plasma etching or wet chemical etching, and/or a combination thereof. For illustrative purposes, the second semiconductor layers 108 are illustrated as dashed lines in FIG. 2D-2 to indicate that they are behind the cross-section. The gate spacer layers 122 and the dummy gate structures 116 may serve as etch masks such that the source/drain recesses 126 are formed self-aligned on opposite sides of the dummy gate structures 116, as shown in FIG. 2D-3. in accordance with some embodiments.

The bottom 126B of the source/drain recess 126 extends into the lower fin element 104L, and the isolation structure 110 is exposed from the source/drain recesses 126, as shown in FIG. 2D, in accordance with some embodiments. The isolation structure 110 is laterally recessed from the source/drain recesses 126, and thus the bottom portion of the source/drain recess 126 may be laterally enlarged toward the isolation structure 110, in accordance with some embodiments. The bottom portion of the source/drain recess 126 may have a curved surface (e.g., convex surface), and extends direct below the fin spacer layers 124, in accordance with some embodiments. In some other embodiments, by adjusting the parameters of the etching process, the isolation structure 110 is not laterally recessed, and the bottom portion of the source/drain recess 126 does not extend direct below the fin spacer layers 124.

The portions of the protection layer 114 uncovered by the dummy gate structure 116, the gate spacer layers 122 and the fin spacer layers 124 are also etched in the etching process and opened to expose the isolation structure 110, as shown in FIG. 2D-2, in accordance with some embodiments. Then in the etching process, the portion of the isolation structure 110 exposed from the protection layer 114 is also vertically and laterally recessed, thereby forming STI recesses 128, as shown in FIGS. 2D-2 and 2D-4, in accordance with some embodiments.

In some embodiments, the bottom 128B of the STI recess 128 extends downward to a deeper position than the bottom 126B of the source/drain recess 126, in accordance with some embodiments. The STI recesses 128 may have a curved surface (e.g., convex surface), and extend direct below the fin spacer layers 124, in accordance with some embodiments.

In some embodiments, after the etching process, the isolation structure 110 includes a protruding portion 110P protruding from between the source/drain recess 126 and the STI recess 128, and has curved sidewalls (e.g., concave sidewalls) exposed from the source/drain recess 126 and the STI recess 128.

Due to the presence of the protection layer 114, the isolation structure 110 may suffer from a lower degree of vertical and lateral recessing than in a case where the protection layer 114 is not formed, in accordance with some embodiments. In the case protection layer 114 is not formed, the STI recess may further laterally enlarge, and the portion of the isolation structure 110 directly under the fin spacer layer 124 will be punched through from both sides (i.e., from source/drain recess-side and STI recess-side) to form a through hole. As a result, the subsequently formed epitaxial material may come out of the through hole, and may merge with neighboring epitaxial material, which may lead to the low yield of the resulting semiconductor device. Therefore, forming the protection layer 114 to reduce the damage of the portion of the isolation structure 110 immediately adjacent to the source/drain region may improve the manufacturing yield of the resulting semiconductor device.

The portions of the protection layer 114 covered by the fin spacer layers 124 remain directly under the fin spacer layers 124, and are referred to as first protection features 114A, as shown in FIGS. 2D-2 and 2D-4, in accordance with some embodiments. In some embodiments, the first protection features 114A extend in the X direction, and each of the first protection features 114A is defined between the source/drain recess 126 and the STI recess 128, as shown in FIG. 2D-4. In some embodiments, the thickness T3 of the protection features 114A is equal or less than the thickness T1 of the bottommost second semiconductor layer 108_1. In some embodiments, the thickness T3 is in a range from about 3.5 nm to about 15 nm.

The fin spacer layers 124 are also recessed in the etching process, and after the etching process, the top of the fin spacer layers 124 is located at a position higher than the bottom surface of the second semiconductor layer 108 that is second from the bottom, as shown in FIG. 2D-2, in accordance with some embodiments. In the etching process, the semiconductor capping layer 109 is also removed to expose the inner sidewalls of the fin spacer layers 124 and the protection features 114A facing the source/drain regions, in accordance with some embodiments.

FIGS. 2E-1, 2E-2 and 2E-3 are cross-sectional views of the semiconductor structure 100 after the formation of inner spacer layers 130 corresponding to line Y1-Y1, line Y2-Y2 and line X-X of FIG. 1, in accordance with some embodiments of the disclosure.

An etching process is performed to laterally recess, from the source/drain recesses 126, the first semiconductor layers 106 of the active region 104, thereby forming notches, and then inner spacer layers 130 are formed in the notches, as shown in FIG. 2E-3, in accordance with some embodiments. The inner spacer layers 130 abut the recessed side surfaces of the first semiconductor layers 106, and are located between adjacent second semiconductor layers 108 and between the lowermost second semiconductor layer 108 and the lower fin element 104L, in accordance with some embodiments. The inner spacer layers 130 may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacer layers 130 are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. In some embodiments, the inner spacer layers 130 are formed by depositing a dielectric material to fill the notches, and then etching away the dielectric material outside the notches. In some embodiments, the deposition process includes ALD, CVD (such as PECVD, LPCVD or HARP), another suitable technique, or a combination thereof. In some embodiments, the etching back process includes an anisotropic etching process such as dry plasma etching, an isotropic etching process such as dry chemical etching, remote plasma etching or wet chemical etching, or a combination thereof.

In the etching process for forming the inner spacer layers 130, the fin spacer layers 124 are also recessed, and after the etching process, the top of the fin spacer layers 124 is located at a position between the top surface and the bottom surface of the second semiconductor layer 108 that is second from the bottom, in accordance with some embodiments.

FIGS. 2F-1, 2F-2 and 2F-3 are cross-sectional views of the semiconductor structure 100 after the formation of semiconductor isolation structures 132, dielectric isolation layers 134, source/drain features 136, a contact etching stop layer (CESL) 138 and an interlayer dielectric layer 140 corresponding to line Y1-Y1, line Y2-Y2 and line X-X of FIG. 1, in accordance with some embodiments of the disclosure. FIG. 2F-4 is a plan view of the semiconductor structure 100 taken along plan A-A in FIG. 2F-1.

Semiconductor isolation layers 132 are grown in the source/drain recesses 126 on the lower fin elements 104L, as shown in FIGS. 2F-2, 2F-3 and 2F-4, in accordance with some embodiments. In some embodiments, the semiconductor isolation layers 132 are made of an epitaxial semiconductor material such as silicon, silicon germanium or germanium, formed by MBE, MOCVD, or VPE, another suitable technique, or a combination thereof. In some embodiments, the semiconductor isolation layers 132 is made of non-doped silicon. In some other embodiments, the semiconductor isolation layers 132 is doped with a dopant that has an opposite conductivity type to the dopant in the subsequently formed source/drain feature.

In some embodiments, the top surface of the semiconductor isolation layers 132 is lower than the tops of the fin spacer layers 124. The semiconductor isolation layers 132 abut and in direct contact with the bottommost second semiconductor layers 108_1, in accordance with some embodiments.

In some embodiments, the semiconductor isolation layers 132 includes a wider bottom portion, which may have a curved surface (e.g., convex surface) and extend direct below the protection features 114A, in accordance with some embodiments.

A dielectric isolation layers 134 are formed on the semiconductor isolation layers 132 in the source/drain recesses 126, as shown in FIGS. 2F-2 and 2F-3, in accordance with some embodiments. In some embodiments, the dielectric isolation layers 134 are made of dielectric material silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the dielectric isolation layers 134 is formed using deposition and etching-back processes.

In some embodiments, the top surface of the dielectric isolation layers 134 is lower than the tops of the fin spacer layers 124, and lower than the bottom surfaces of the second semiconductor layers 108 that are second from the bottom. In some embodiments, the semiconductor isolation feature 132 and the dielectric isolation features 134 are together configured to block the leakage path of the bottom planar transistor formed from the lower fin elements.

Afterward, the source/drain features 136 are grown from the exposed side surfaces of the second semiconductor layers 108 in the source/drain recesses 126 using an epitaxial growth process, as shown in FIGS. 2F-2 and 2F-3, in accordance with some embodiments. In some embodiments, the side surfaces (previously exposed from the source/drain recesses 126) of the bottommost second semiconductor layer 108_1 are covered by the semiconductor isolation layers 132 (and/or the dielectric isolation layer 134), and thus the source/drain features 136 do not grow on the side surfaces of the bottommost second semiconductor layer 108_1. The epitaxial growth process may be molecular beam epitaxy (MBE), metal organic chemical vapor deposition (MOCVD), or vapor phase epitaxy (VPE), or another suitable technique.

The growth of the source/drain features 136 is initially confined by the fin spacer layers 124 such that the source/drain features 136 have a narrow body portion between the fin spacer layers 124, in accordance with some embodiments. Once the source/drain features 136 grow to protrude from the fin spacer layers 124, the source/drain features 136 may grow to have facet surfaces that have specific crystalline orientations such that the source/drain features 136 has a wider head portion. Although the source/drain features 136 are illustrated as having facet surfaces, the surface of the source/drain features 136 may have curved in some other embodiments.

In some embodiments, the source/drain features 136 are made of any suitable semiconductor material for n-type semiconductor devices or p-type semiconductor devices. In some embodiments, the source/drain features 136 are doped. The concentration of the dopant in the source/drain features 136 in a range from about 1×10¹⁹ cm⁻³ to about 6×10²¹ cm⁻³. An annealing process may be performed on the semiconductor structure 100 to activate the dopants in the source/drain features 136, in accordance with some embodiments.

In some embodiments wherein the active region 104 is to be formed as an N-type nanostructure device (such as n-channel GAA FET), the source/drain features 136 are made of semiconductor material such as SiP, SiAs, SiCP, SiC, Si, GaAs, another suitable semiconductor material, or a combination thereof. In some embodiments, the source/drain features 136 are doped with the n-type dopant during the epitaxial growth process. For example, the n-type dopant may be phosphorous (P) or arsenic (As). For example, the source/drain features 136 may be the epitaxially grown Si doped with phosphorous to form silicon:phosphor (Si:P) source/drain features and/or arsenic to form silicon:arsenic (Si:As) source/drain feature.

In some embodiments wherein the active region 104 is to be formed as a P-type nanostructure device (such as p-channel GAA FET), the source/drain features 136 are made of semiconductor material such as SiGe, Si, GaAs, another suitable semiconductor material, or a combination thereof. In some embodiments, the source/drain features 136 are doped with the p-type dopant during the epitaxial growth process. For example, the p-type dopant may be boron (B) or BF₂. For example, the source/drain features 136 may be the epitaxially grown SiGe doped with boron (B) to form silicon germanium:boron (SiGe:B) source/drain feature.

In some embodiments, the source/drain features 136 may be multilayered structures, e.g., including sequentially formed epitaxial layers L1 and L2. In some embodiments, the concentration of the dopant in the epitaxial layer L2 is higher than the concentration of the dopant in the epitaxial layer L1, e.g., by 1-2 orders.

In accordance with some embodiments of the present disclosure, forming the protection layer 114 may prevent the formation of the punch-through hole in the isolation structure 110, which may prevent the neighboring epitaxial materials (from the semiconductor isolation layer 132 and/or the source/drain feature 136) from merging with each other, thereby improving the manufacturing yield of the resulting semiconductor device.

A contact etching stop layer 138 is formed over the semiconductor structure 100 to cover the source/drain features 136, as shown in FIGS. 2F-2 and 2F-3, in accordance with some embodiments. The contact etching stop layer 138 is further formed along, and covers, the sidewalls of the gate spacer layers 122, the top and sidewalls of the fin spacer layers 124, the sidewalls of the protection features 114A and the top surface of the isolation structure 110, in accordance with some embodiments.

In some embodiments, the contact etching stop layer 138 partially fills the STI recesses 128. In some embodiments, the bottom 138B of the contact etching stop layer 138 is located at a lower position than the top 104LT of the lower fin element 104L.

In some embodiments, the contact etching stop layer 138 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, dielectric material for the contact etching stop layer 138 is globally and conformally deposited over the semiconductor structure 100 using CVD (such as LPCVD, PECVD, HDP-CVD, or HARP), ALD, another suitable method, or a combination thereof.

In some embodiments, each of the first protection features 114A is defined between the semiconductor isolation layer 132 and the contact etching stop layer 138, as shown in FIG. 2F-4.

Afterward, an interlayer dielectric layer 140 is formed over the contact etching stop layer 138, as shown in FIGS. 2F-2 to 2F-4, in accordance with some embodiments. The interlayer dielectric layer 140 overfills the space between dummy gate structures 116, in accordance with some embodiments. The interlayer dielectric layer 140 also overfills the remainder of the STI recesses 128, in accordance with some embodiments.

In some embodiments, the interlayer dielectric layer 140 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material.

In some embodiments, the interlayer dielectric layer 140 and the contact etching stop layer 138 are made of different materials and have a great difference in etching selectivity. In some embodiments, the dielectric material for the interlayer dielectric layer 140 is deposited using such as CVD (such as HDP-CVD, PECVD, HARP or FCVD), another suitable technique, or a combination thereof. The dielectric materials for the contact etching stop layer 138 and the interlayer dielectric layer 140 above the top surface of the dummy gate electrode layer 120 are removed using such as CMP, in accordance with some embodiments. In some embodiments, the bottom 140B of the interlayer dielectric layer 140 may be located at a lower position than the top 104LT of the lower fin element 104L.

FIGS. 2G-1, 2G-2 and 2G-3 are cross-sectional views of the semiconductor structure 100 after the formation of gate trenches 142 and gaps 144 corresponding to line Y1-Y1, line Y2-Y2 and line X-X of FIG. 1, in accordance with some embodiments of the disclosure. FIG. 2G-4 is a plan view of the semiconductor structure 100 taken along plan A-A in FIG. 2G-1.

The dummy gate structures 116 and the semiconductor capping layer 109 are removed using an etching process to form gate trenches 142 between the gate spacer layers 122, as shown in FIGS. 2G-1 and 2G-3, in accordance with some embodiments. In some embodiments, the gate trenches 142 expose the channel regions of the active region 104 and the top surface of the protection layer 114. In some embodiments, the gate trenches 142 further expose the sidewalls of the gate spacer layers 122 facing the channel region. In some embodiments, the etching process includes one or more etching processes. For example, when the dummy gate electrode layer 120 is made of polysilicon, a wet etchant such as a tetramethylammonium hydroxide (TMAH) solution may be used to selectively remove the dummy gate electrode layer 120. For example, the dummy gate dielectric layer 118 may be thereafter removed using a plasma dry etching, a dry chemical etching, and/or a wet etching.

Afterward, an etching process is performed on the first semiconductor layers 106 other than the bottommost first semiconductor layer 106_1 to form gaps 144, as shown in FIGS. 2G-1 and 2G-3, in accordance with some embodiments. The inner spacer layers 130 may be used as an etching stop layer in the etching process, which may protect the source/drain features 136 from being damaged. In some embodiments, the etching process includes a selective wet etching process, such as APM (e.g., ammonia hydroxide-hydrogen peroxide-water mixture) etching process. In some embodiments, the wet etching process uses etchants such as ammonium hydroxide (NH₄OH), TMAH, ethylenediamine pyrocatechol (EDP), and/or potassium hydroxide (KOH) solutions. In some embodiments, a corner-rounding process may be optionally performed on the nanostructures 108.

The gaps 144 are formed between adjacent second semiconductor layers 108, in accordance with some embodiments. In some embodiments, the gaps 144 also expose the sidewalls of the inner spacer layers 130 facing the channel region.

After the one or more etching processes, the main surfaces of the second semiconductor layers 108 are exposed, in accordance with some embodiments. The exposed second semiconductor layers 108 form nanostructures, in accordance with some embodiments. The nanostructures 108 are vertically stacked and spaced apart from one other, in accordance with some embodiments. The nanostructures 108 function as channels of the resulting semiconductor devices (e.g., nanostructure transistors such as GAA transistors), in accordance with some embodiments.

These etching processes also thin down the portion of the protection layer 114 exposed from the gate trenches 142, in accordance with some embodiments. The thinned protection layer 114 is referred to as second protection features 114B, as shown in FIG. 2G-1, in accordance with some embodiments. In some embodiments, the second protection features 114B extend in the Y direction between the bottommost second semiconductor layers 108_1, as shown in FIG. 2G-4. In some embodiments, the second protection features 114B have a thickness T4 (in the Z direction) that is less than the thickness T3 of the first protection features 114A. In some embodiments, thickness T4 is in a range from about 2.5 nm to about 11 nm.

In some embodiments, the top 114T′ of the second protection features 114B is located at a position between the second protection features 114B and the bottom surface of the bottommost second semiconductor layer 108_1, in accordance with some embodiments. The sidewalls of the bottommost first semiconductor layer 106_1 remain covered by the isolation structure 110 and/or the second protection features 114B, and thus the bottommost first semiconductor layer 106_1 remains unetched.

In accordance with some embodiments of the present disclosure, forming the protection layer 114 may reduce the damage of the portion of the isolation structure 110 immediately adjacent to the channel regions, which may prevent subsequently formed final gate stacks from enlarging toward the isolation structure 110.

FIGS. 2H-1, 2H-2 and 2H-3 are cross-sectional views of the semiconductor structure 100 after the formation of final gate stacks 146 and contact plugs 153 corresponding to line Y1-Y1, line Y2-Y2 and line X-X of FIG. 1, in accordance with some embodiments of the disclosure.

Final gate stacks 146 are formed in the gate trenches 142 and gaps 144, as shown in FIGS. 2H-1 and 2H-3, in accordance with some embodiments. The nanostructures 108 are wrapped by the final gate stacks 146, in accordance with some embodiments. In some embodiments, the final gate stacks 146 extend in the Y direction. The final gate stacks 146 have longitudinal axes parallel to the Y direction, in accordance with some embodiments.

The final gate stacks 146 engage the channel region so that current can flow between the source/drain features 136 during operation. In some embodiments, each of the final gate stacks 146 includes an interfacial layer 148, a gate dielectric layer 150 and a metal gate electrode layer 152, as shown in FIGS. 2H-1 and 2H-3, in accordance with some embodiments.

The interfacial layer 148 is formed on the exposed surfaces of the nanostructures 108, in accordance with some embodiments. The interfacial layer 148 wraps around the nanostructures 108, in accordance with some embodiments. In some embodiments, the interfacial layer 148 is made of a chemically formed silicon oxide. In some embodiments, the interfacial layer 148 is nitrogen-doped silicon oxide. In some embodiments, the interfacial layer 148 is formed using one or more cleaning processes such as including ozone (O₃), ammonia hydroxide-hydrogen peroxide-water mixture, and/or hydrochloric acid-hydrogen peroxide-water mixture. Semiconductor material from the nanostructures 108 is oxidized to form the interfacial layer 148, in accordance with some embodiments.

The gate dielectric layer 150 is formed conformally along the interfacial layer 148 to wrap around the nanostructures 108, in accordance with some embodiments. The gate dielectric layer 150 is also conformally formed along the sidewalls of the gate spacer layers 122 facing the channel region, in accordance with some embodiments. The gate dielectric layer 150 is also conformally formed along the sidewalls of the inner spacer layers 130 facing the channel region, in accordance with some embodiments. The gate dielectric layer 150 is further formed along the top surface of the second protection features 114B, in accordance with some embodiments.

The gate dielectric layer 150 may be high-k dielectric layer. In some embodiments, the high-k dielectric layer is dielectric material with high dielectric constant (k value), for example, greater than 9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr) TiO₃ (BST), Si₃N₄, oxynitrides (SiON), a combination thereof, or another suitable material. The high-k dielectric layer may be deposited using ALD, PVD, CVD, and/or another suitable technique.

The metal gate electrode layer 152 is formed to overfill remainders of the gate trenches 142 and gaps 144, in accordance with some embodiments. In some embodiments, the metal gate electrode layer 152 is made of more than one conductive material, such as a metal, metal alloy, conductive metal oxide and/or metal nitride, another suitable conductive material, and/or a combination thereof. For example, the metal gate electrode layer 152 may be made of Ti, Ag, Al, TiAlN, TaC, TaCN, TaSiN, Mn, Zr, TiN, TaN, Ru, Mo, WN, Cu, W, Re, Ir, Co, Ni, another suitable conductive material, or multilayers thereof.

The metal gate electrode layer 152 may be a multi-layer structure with various combinations of a diffusion barrier layer, work function layers with a selected work function to enhance the device performance (e.g., threshold voltage) for n-channel FETs or p-channel FETs, a capping layer to prevent oxidation of work function layers, a glue layer to adhere work function layers to the next layer, and a metal fill layer to reduce the total resistance of gate stacks, and/or another suitable layer. The metal gate electrode layer 152 may be formed using ALD, PVD, CVD, e-beam evaporation, or another suitable technique.

A planarization process such as CMP may be performed on the semiconductor structure 100 to remove the materials of the gate dielectric layer 150 and the metal gate electrode layer 152 formed above the top surface of the interlayer dielectric layer 140, in accordance with some embodiments. The final gate stacks 146 that are wrapped around the nanostructures 108 combine with the neighboring source/drain features 136 to form nanostructure transistors, e.g., n-channel nanostructure transistors and p-channel nanostructure transistors.

In accordance with the embodiments of the present disclosure, forming the protection layer 114 may reduce the damage of the portion of the isolation structure 110 immediately adjacent to the channel regions, which may prevent the enlargement of the final gate stacks 146 toward the isolation structure 110. Therefore, the parasitic capacitance between the gate stack and the source/drain features (i.e., Cgs and Cgd) may be improved, thereby enhancing the performance (e.g., speed) of the resulting semiconductor device, in accordance with some embodiments.

In addition, due to the formation of the protection layer 114, the bottommost first semiconductor layer 106_1 remains and is not replaced by the final gate stack 146, which may reduce the risk of leakage between the final gate stack 146 and a subsequently formed backside contact plug, in accordance with some embodiments. Therefore, the manufacturing yield of the resulting semiconductor device may improve.

Contact plugs 153 are formed through the interlayer dielectric layer 140 and the contact etching stop layer 138, as shown in FIGS. 2H-2 and 2H-3, in accordance with some embodiments. The contact plugs 153 land on and are electrically connected to the source/drain features 136, in accordance with some embodiments. The contact plugs 153 may be also referred to as frontside contact plugs 153.

In some embodiments, the formation of the contact plugs 153 includes patterning the semiconductor structure 100 to form contact openings (where the contact plugs 153 are to be formed) using photolithography and etching processes until the source/drain features 136 are exposed. The etch process may include dry etching such as reactive ion etch (RIE), neutral beam etch (NBE), inductive coupled plasma (ICP) etch, capacitively coupled plasma (CCP) etch, another suitable method, or a combination thereof.

Silicide layers 154 are formed on the exposed surfaces of the source/drain features 136. In some embodiments, the silicide layers 150 are made of WSi, NiSi, TiSi and/or CoSi. In some embodiments, the formation of the silicide layers 150 includes depositing a metal material followed by one or more annealing processes. The semiconductive material (e.g., Si) from the source/drain features 136 reacts with the metal material to form the silicide layers 150, in accordance with some embodiments. Unreacted metal material is then removed, e.g., using wet etching.

Afterward, one or more conductive materials for the contact plugs 153 are deposited to overfill the contact openings, in accordance with some embodiments. In some embodiments, one or more conductive materials are deposited using CVD, PVD, e-beam evaporation, ALD, electroplating (ECP), electroless deposition (ELD), another suitable method, or a combination thereof to overfill the contact openings. The one or more conductive materials over the upper surface of the second interlayer dielectric layer 146 are planarized using, for example, CMP.

The contact plugs 153 may have a multilayer structure. For example, a barrier/adhesive layer (not shown) may optionally be deposited along the sidewalls and the bottom surfaces of the contact openings. The barrier/adhesive layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the contact openings. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

The semiconductor structure 100 may undergo further frontside MEOL and/or BEOL processes to form various interconnection conductive features (not shown) over the semiconductor structure 100, such as frontside metal layers and vias between neighboring two metal layers.

FIGS. 2I-1, 2I-2 and 2I-3 are cross-sectional views of the semiconductor structure 100 after an upside-down flip corresponding to line Y1-Y1, line Y2-Y2 and line X-X of FIG. 1, in accordance with some embodiments of the disclosure.

The semiconductor structure 100 is flipped upside down, as shown FIGS. 2I-1 to 21-3, in accordance with some embodiments. In some embodiments, a carrier substrate (not shown) may be formed over and seal the frontside of the semiconductor structure 100 before flipping the semiconductor structure 100 to protect the frontside components of the semiconductor structure 100 during subsequent backside processes. After flipping the semiconductor structure 100, the backside surface of the substrate 102 (the backside of the semiconductor structure 100) faces upward, in accordance with some embodiments.

FIGS. 2J-1, 2J-2 and 2J-3 are cross-sectional views of the semiconductor structure 100 after a planarization process corresponding to line Y1-Y1, line Y2-Y2 and line X-X of FIG. 1, in accordance with some embodiments of the disclosure.

The substrate 102 is planarized from the backside of the semiconductor structure 100 using such as CMP, a grinding process, an etching process, or a combination thereof so that the isolation structure 110 is exposed, as shown in FIGS. 2J-1 to 2J-3, in accordance with some embodiments. In some embodiments, the lower fin element 104L is also thinned down.

FIGS. 2K-1, 2K-2 and 2K-3 are cross-sectional views of the semiconductor structure 100 after the formation of a mask layer 156 and a patterned photoresist layer 158 corresponding to line Y1-Y1, line Y2-Y2 and line X-X of FIG. 1, in accordance with some embodiments of the disclosure.

A mask layer 156 and a patterned photoresist layer 158 are subsequently formed over the backside of the semiconductor structure 100, as shown in FIGS. 2K-1 to 2K-3, in accordance with some embodiments. The mask layer 156 is made of one or more dielectric materials such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. In some other embodiments, the patterned photoresist layer 158 may be made of metal oxide (e.g., AlO, TiO, LaO, HfO, etc.), a nitrogen-free anti-reflection layer (NFARL), carbon-doped silicon dioxide (e.g., SiO₂:C), titanium nitride (TiN), boron nitride (BN), a multilayer thereof, another suitable material, or a combination thereof. In some embodiments, the mask layer 156 is deposited using ALD, CVD (such as PECVD, LPCVD or HARP), another suitable technique, or a combination thereof.

The patterned photoresist layer 158 has an opening pattern 160 which exposes the mask layer 156 and corresponds to (or overlaps) one source/drain feature 136, as shown in FIGS. 2K-2 and 2K-3, in accordance with some embodiments. In some embodiments, the patterned photoresist layer 158 is a patterned photoresist layer. For example, a photoresist may be formed over the backside of the semiconductor structure 100 such as by using spin-on coating, and patterned by exposing the photoresist to light using an appropriate photomask. Exposed or unexposed portions of the photoresist may be removed depending on whether a positive or negative resist is used.

FIGS. 2L-1, 2L-2 and 2L-3 are cross-sectional views of the semiconductor structure 100 after an etching process corresponding to line Y1-Y1, line Y2-Y2 and line X-X of FIG. 1, in accordance with some embodiments of the disclosure. FIG. 2L-4 is a plan view of the semiconductor structure 100 taken along plan A-A in FIG. 2L-1.

An etching process is performed on the semiconductor structure 100 using the patterned photoresist layer 158 to form a contact opening 162 through the mask layer 156, the lower fin element 104L, the semiconductor capping layer 109, the semiconductor isolation layer 132 and the dielectric isolation layer 134 until the source/drain feature 136 is exposed, as shown in FIGS. 2L-2, 2L-3 and 2L-4, in accordance with some embodiments. The etching process may include dry etching such as RIE, NBE, ICP etch, CCP etch, another suitable method, or a combination thereof. The contact opening 162 also exposes the sidewalls of the fin spacer layers 124 and the first protection features 114A, as shown in FIG. 2L-2, in accordance with some embodiments.

In some embodiments, the contact opening 162 also exposes the sidewalls of the inner spacer layers 130_1 (which are the bottommost inner spacer layers when the frontside of the semiconductor structure 100 faces upward) and the bottommost second semiconductor layers 108_1 (i.e., the topmost second semiconductor layers in the current schematics).

Because the inner spacer layers 130 have a different etching selectivity than the mask layer 156, the lower fin element 104L, the semiconductor capping layer 109, the semiconductor isolation layer 132 and the dielectric isolation layer 134, the inner spacer layers 130_1 may be used to control the self-alignment of the contact opening 162 with the source/drain feature 136, in accordance with some embodiments. The inner spacer layers 130_1 may prevent the subsequently formed contact plug from being too close to the final gate stack 146 when the overlay and CD of the photolithography process for forming the opening pattern 160 are shifted. Therefore, the overlay and CD (critical dimension) window of the photolithography process for forming the opening pattern 160 may be relaxed.

FIGS. 2M-1, 2M-2 and 2M-3 are cross-sectional views of the semiconductor structure 100 after the formation of a contact plug 164 corresponding to line Y1-Y1, line Y2-Y2 and line X-X of FIG. 1, in accordance with some embodiments of the disclosure. FIG. 2M-4 is a plan view of the semiconductor structure 100 taken along plan A-A in FIG. 2M-1.

The contact plug 164 is formed in the contact opening 162, as shown in FIGS. 2M-2, 2M-3 and 2M-4, in accordance with some embodiments. The contact plug 164 lands on and is electrically connected to the source/drain feature 136, in accordance with some embodiments. The contact plug 164 may be also referred to as a backside contact plug 164.

In some embodiments, the formation of the contact plug 164 includes forming a silicide layer 166 on the exposed surface of the source/drain features 136. In some embodiments, the silicide layer 166 is made of WSi, NiSi, TiSi and/or CoSi. In some embodiments, the formation of the silicide layer 166 includes depositing a metal material followed by one or more annealing processes. The semiconductive material (e.g., Si) from the source/drain feature 136 reacts with the metal material to form the silicide layers 166, in accordance with some embodiments. Unreacted metal material is then removed, e.g., using wet etching.

Contact liner 168 is formed along the sidewalls of the contact opening 162 using a deposition process and an etching back process, in accordance with some embodiments. In some embodiments, the contact liner 168 is made of an insulating material such as a dielectric material (e.g., SiC, LaO, AlO, AION, ZrO, HfO, SiN, ZnO, ZrN, ZrAlO, TiO, TaO, YO, TaCN, ZrSi, SiOCN, SiOC, SiCN, SiN, HfSi, or SiO); or undoped silicon (Si).

Afterward, one or more conductive materials for the contact plug 164 are deposited to overfill the contact opening 162, in accordance with some embodiments. In some embodiments, one or more conductive materials are deposited using CVD, PVD, e-beam evaporation, ALD, ECP, ELD, another suitable method, or a combination thereof to overfill the contact openings. The one or more conductive materials over the upper surface of the isolation structure 110 are planarized using, for example, CMP. In some embodiments, the mask layer 156 and the patterned photoresist layer 158 are also removed.

The contact plug 164 may have a multilayer structure. For example, a barrier/adhesive layer (not shown) may optionally be deposited along the sidewalls and the bottom surface of the contact opening 162. The barrier/adhesive layer may be made of Ta, TaN, Ti, TiN, CoW, another suitable material, or a combination thereof. A metal bulk layer is then deposited on the barrier/adhesive layer (if formed) to fill the remainder of the contact opening 162. In some embodiments, the metal bulk layer is made of one or more conductive materials with low resistance and good gap-fill ability, for example, Co, Ni, W, Ti, Ta, Cu, Rh, Ir, Pt, Al, Ru, Mo, another suitable metal material, or a combination thereof.

The contact plug 164 is formed self-aligned with the source/drain feature 136 due to the existence of the inner spacer layers 130_1, which may reduce the risk of leakage between the contact plug 164 and the final gate stack 146, thereby improving the manufacturing yield of the resulting semiconductor device, in accordance with some embodiments.

FIGS. 2N-1, 2N-2 and 2N-3 are cross-sectional views of the semiconductor structure 100 after the formation of an intermetal dielectric layer 170 and a backside metal layer 172 corresponding to line Y1-Y1, line Y2-Y2 and line X-X of FIG. 1, in accordance with some embodiments of the disclosure. FIGS. 2N-1, 2N-2 and 2N-3 illustrate the semiconductor structure 100 that has been flipped upside down, with the frontside of the semiconductor structure 100 facing upward.

An intermetal dielectric layer 170 is formed over the backside of the semiconductor structure 100, and a backside metal layer 172 is formed in and/or through the intermetal dielectric layer 170, as shown in FIGS. 2N-1, 2N-2 and 2N-3, in accordance with some embodiments. The intermetal dielectric layer 170 is made of one or more dielectric materials, such as silicon oxide (SiO), silicon nitride (SiN), silicon oxynitride (SiON), silicon carbide (SiC), aluminum oxide (Al₂O₃), dielectric material(s) with low dielectric constant (low-k) such as SiCOH, SiOCN, and/or SiOC, or a combination thereof.

In some embodiments, the intermetal dielectric layer 170 is made of an extreme low-k (ELK) dielectric material with a dielectric constant (k) less than about 3.0, or even less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon oxide (SiO₂). In some embodiments, the intermetal dielectric layer 170 is formed using CVD (such as LPCVD, HARP, and FCVD), ALD, spin-on coating, another suitable method, or a combination thereof. A post-curing process (e.g., UV curing) may be performed on the as-deposited ELK dielectric material for the intermetal dielectric layer 170 to form a porous structure.

The backside metal layer 172 extends in the X direction, in accordance with some embodiments. The backside metal layer 172 is in direct contact with and electrically connected to the contact plug 164, and further electrically connected to the frontside contact plug 153 through the source/drain feature 136, in accordance with some embodiments. The backside metal layer 172 is a power supply line, in accordance with some embodiments. For example, the power supply line may be a Vdd power rail providing positive voltage or a Vss power rail which may be an electrical ground, in accordance with some embodiments.

The formation of the backside metal layer 172 includes patterning the intermetal dielectric layer 170 using photolithography and etching processes to form a trench. The etching process may include dry etching such as RIE, NBE, ICP etch, CCP etch, another suitable method, or a combination thereof. One or more conductive materials for the backside metal layer 172 are then deposited using CVD, PVD, e-beam evaporation, ALD, ECP, ELD, another suitable method to overfill the trenches. Afterward, a planarization process such as CMP and/or an etching back process is performed to remove an excess portion of the conductive materials from the upper surface of the intermetal dielectric layer 170.

The backside metal layer 172 may have a multilayer structure. For example, a barrier/adhesive layer (not shown) may optionally be deposited along the sidewalls and the bottom surface of the trench. The barrier layer may be made of Ta, TaN, Ti, TiN, CoW, another suitable material, or a combination thereof. A metal bulk layer is then deposited on the barrier/adhesive layer (if formed) to fill the remainder of the trench. In some embodiments, the metal bulk layer is made of one or more conductive materials, such as Co, Ni, W, Ti, Ta, Cu, Rh, Ir, Pt, Al, Ru, Mo, another suitable metal material, or a combination thereof.

The semiconductor structure 100 may undergo further backside BEOL processes to form various interconnection conductive features (not shown) over the backside of the semiconductor structure 100, such as other backside second metal layers, vias between neighboring two metal layers, passivation layers, bump pads, etc.

FIGS. 3A-1 through 3B-3 are cross-sectional views illustrating the formation of a semiconductor structure 200 at various intermediate stages. The embodiments of FIGS. 3A-1 through 3B-3 are similar to the embodiments of FIGS. 2A-1 to 2N-3 except that the semiconductor structure 200 is used to form nanostructure transistors without a backside power rail architecture.

FIGS. 3A-1, 3A-2 and 3A-3 are cross-sectional views of the semiconductor structure 200 after the formation of inner spacer layers 130 corresponding to line Y1-Y1, line Y2-Y2 and line X-X of FIG. 1, in accordance with some embodiments of the disclosure.

The active region 104 is formed over the substrate 102, the isolation structure 110 is formed to surround the lower fin element 104L of the active region 104, and the protection layer 114 is formed over the isolation structure 110, as shown in FIGS. 3A-1, 3A-2 and 3A-3, in accordance with some embodiments. The active region 104 includes three first semiconductor layers 106 and three second semiconductor layers 108, in accordance with some embodiments.

In some embodiments, the top surface of the isolation structure 110 is lower than the top surface of the lower fin element 104L by a distance D1. In some embodiments, the distance D1 is less than 30 nm, e.g., in a range from about 20 nm to 30 nm. In some embodiments, the top surface of the protection layer 114 is lower than the top surface of the lower fin element 104L by a distance D2. In some embodiments, the distance D2 is less than 10 nm.

The dummy gate structure 116 is formed across the active region 104 and the protection layer 114, the gate spacer layers 116 are formed on opposite sides of the dummy gate structure 116, the source/drain recesses 126 are formed in the active region 104 and the STI recesses 128 are formed in the isolation structure 110, as shown in FIGS. 3A-1, 3A-2 and 3A-3, in accordance with some embodiments. The inner spacer layers 130 are formed on the sidewalls of the first semiconductor layers 106, in accordance with some embodiments.

FIGS. 3B-1, 3B-2 and 3B-3 are cross-sectional views of the semiconductor structure 200 after the formation of final gate stacks 146 and contact plugs 153 corresponding to line Y1-Y1, line Y2-Y2 and line X-X of FIG. 1, in accordance with some embodiments of the disclosure.

The semiconductor isolation layer 132 is formed on the lower fin element 104L, the dielectric isolation structure 134 is formed on the semiconductor isolation layer 132, and the source/drain features 136 are formed to fill the source/drain recesses 126, as shown in FIGS. 3B-1, 3B-2 and 3B-3, in accordance with some embodiments.

In accordance with the embodiments of the present disclosure, forming the protection layer 114 to reduce the damage of the portion of the isolation structure 110 immediately adjacent to the source/drain region may prevent the neighboring epitaxial material from merging with each other, thereby improving the manufacturing yield of the resulting semiconductor device.

The contact etching stop layer 138 is formed to cover the source/drain feature 136, and the interlayer dielectric layer 140 is formed over the contact etching stop layer 138 and fills the STI recess 128 as shown in FIGS. 3B-1, 3B-2 and 3B-3, in accordance with some embodiments. The dummy gate structure 116 and the first semiconductor layers 106 are replaced with the final gate stacks 146, and the contact plugs 153 are formed through the interlayer dielectric layer 140 and the contact etching stop layer 138 and land on the source/drain feature 136, as shown in FIGS. 3B-1, 3B-2 and 3B-3, in accordance with some embodiments.

In accordance with the embodiments of the present disclosure, forming the protection layer 114 may reduce the damage of the portion of the isolation structure 110 immediately adjacent to the channel regions, which may prevent the enlargement of the final gate stacks 146 toward the isolation structure 110. Therefore, the parasitic capacitance between the gate stack and the source/drain features may be improved, thereby enhancing the performance (e.g., speed) of the resulting semiconductor device, in accordance with some embodiments.

As described above, the method for forming the semiconductor structure includes forming the isolation structure 110 surrounding the lower portion of the fin structure 104, and forming the protection layer 114 over the isolation structure 110. During the etching process for forming the source/drain recesses 126, the protection layer 114 may reduce the damage of the etching to the isolation structure 110, thereby preventing the neighboring epitaxial material from merging with each other. In addition, During the etching process for forming the gate trenches 142 and gaps 144, the protection layer 114 may protect the isolation structure 110 from being damaged, thereby preventing the enlargement of the final gate stacks 146 toward the isolation structure 110. Therefore, the manufacturing yield and the performance of the resulting semiconductor device may improve, in accordance with some embodiments.

Embodiments of a semiconductor structure and the method for forming the same may be provided. The semiconductor structure may include nanostructures over a lower fin element, an isolation structure surrounding the lower fin element, a protection feature over the isolation structure, and a gate stack over the protection feature and surrounding nanostructures. The protection layer may protect the isolation structure from being damaged, thereby preventing the enlargement of the final gate stack. Therefore, the performance of the resulting semiconductor device may improve.

The method for forming the semiconductor structure includes forming a spacer layer along dummy gate structures, active regions and an isolation structure, and forming a sacrificial material over the spacer layer. The sacrificial material and the protection layer may protect the underlying isolation structure from being recessed in the etching processes. As a result, the risk that the dummy gate structures collapse and the risk that the active regions are exposed may decrease. Therefore, the reliability, manufacturing yield and performance of the resulting semiconductor structure may increase.

In some embodiments, a method for forming a semiconductor structure is provided. The method includes forming a fin structure over a substrate, forming an isolation structure surrounding a lower portion of the fin structure, forming a protection layer over the isolation structure, etching the fin structure, the protection layer and the isolation structure to form a first recess in the fin structure and a second recess in the isolation structure, forming a source/drain feature to fill the first recess, and forming an interlayer dielectric layer over the source/drain feature and filling the second recess.

In some embodiments, a method for forming a semiconductor structure is provided. The method includes forming a fin structure over a substrate. The fin structure includes a lower fin element and sacrificial layers and channel layers alternately stacked over the lower fin element. The method also includes forming an isolation structure adjacent to the lower fin element, forming a protection layer over the isolation structure, forming a dummy gate structure across the fin structure and the protection layer, removing the dummy gate structure to expose the fin structure and the protection layer, and removing the sacrificial layers to expose the channel layers. The protection layer protects the isolation layer while the dummy gate structure and the sacrificial layers are being removed. The method also includes forming a gate stack surrounding the channel layers and across the protection layer.

In some embodiments, a semiconductor structure is provided. The semiconductor structure includes a lower fin element extending in a horizontal direction, an isolation structure surrounding the lower fin element, a first nanostructure over the lower fin element, a first protection feature over the isolation structure and surrounding the first nanostructure, a second nanostructure over the first nanostructure, and a gate stack surrounding the second nanostructure and covering the first protection feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a fin structure over a substrate;
forming an isolation structure surrounding a lower portion of the fin structure;
forming a protection layer over the isolation structure;
etching the fin structure, the protection layer and the isolation structure to form a first recess in the fin structure and a second recess in the isolation structure;
forming a source/drain feature to fill the first recess; and
forming an interlayer dielectric layer over the source/drain feature and filling the second recess.

2. The method for forming the semiconductor structure as claimed in claim 1, further comprising:
forming fin spacer layers over the protection layer to surround an upper portion of the fin structure, wherein after etching the fin structure, the protection layer and the isolation structure, a portion of the protection layer remains under the fin spacer layers.

3. The method for forming the semiconductor structure as claimed in claim 2, wherein a portion of the first recess extends directly below the portion of the protection layer under the fin spacer layers.

4. The method for forming the semiconductor structure as claimed in claim 2, wherein a portion of the second recess extends directly below the first portion of the protection layer under the fin spacer layers.

5. The method for forming the semiconductor structure as claimed in claim 1, wherein the fin structure includes a lower fin element and SiGe layers and Si layers alternately stacked on the lower fin element, a bottommost one in the Si layers is a first Si layer, and the first Si layer is thicker than the other Si layers.

6. The method for forming the semiconductor structure as claimed in claim 5, wherein a top of the protection layer is located between a top surface and a bottom surface of the first Si layer.

7. The method for forming the semiconductor structure as claimed in claim 5, further comprising:
forming a dummy gate structure over the fin structure and the protection layer; and
removing the dummy gate structure and the SiGe layers to form gaps between the Si layers, wherein a portion of the protection layer under the dummy gate structure is thinned down while removing the dummy gate structure and the SiGe layers.

8. The method for forming the semiconductor structure as claimed in claim 5, further comprising:
laterally recessing the SiGe layers to form notches; and
forming inner spacer layers in the notches on the SiGe layers.

9. The method for forming the semiconductor structure as claimed in claim 8, further comprising:
removing the substrate;
etching the lower fin element to form an opening exposing the source/drain feature, wherein one of the inner spacer layers is exposed from the opening; and
forming a contact plug to fill the opening.

10. The method for forming the semiconductor structure as claimed in claim 1, further comprising:
forming a dielectric layer along a top surface of the isolation structure and a sidewall and a top surface of the fin structure; and
removing a portion of the dielectric layer along the sidewall and the top surface of the fin structure, wherein a portion of the dielectric layer along the top surface of the isolation structure forms the protection layer.

11. A method for forming a semiconductor structure, comprising:
forming a fin structure over a substrate, wherein the fin structure includes a lower fin element and sacrificial layers and channel layers alternately stacked over the lower fin element;
forming an isolation structure adjacent to the lower fin element;
forming a protection layer over the isolation structure;
forming a dummy gate structure across the fin structure and the protection layer;
removing the dummy gate structure to expose the fin structure and the protection layer;
removing the sacrificial layers to expose the channel layers, wherein the protection layer protects the isolation layer while the dummy gate structure and the sacrificial layers are being removed; and
forming a gate stack surrounding the channel layers and across the protection layer.

12. The method for forming the semiconductor structure as claimed in claim 11, wherein a bottommost one in the sacrificial layers is a first sacrificial layer, a top of the protection layer is higher than a top of the first sacrificial layer, and the first sacrificial layer remains after the sacrificial layers are removed.

13. The method for forming the semiconductor structure as claimed in claim 11, further comprising:
etching the fin structure to form a source/drain recess, wherein during etching the fin structure to form the source/drain recess, the protection layer and the isolation structure are also recessed; and
growing an epitaxial material in the source/drain recess.

14. The method for forming the semiconductor structure as claimed in claim 13, further comprising:
forming a contact etching stop layer over the epitaxial material; and
forming an interlayer dielectric layer over the contact etching stop layer, wherein a bottom of the interlayer dielectric layer is lower than a bottom of the epitaxial material.

15. The method for forming the semiconductor structure as claimed in claim 11, wherein a top of the lower fin element is higher than a top of the protection layer.

16. A semiconductor structure, comprising:
a lower fin element extending in a horizontal direction;
an isolation structure surrounding the lower fin element;
a first nanostructure over the lower fin element;
a first protection feature over the isolation structure and surrounding the first nanostructure;
a second nanostructure over the first nanostructure; and
a gate stack surrounding the second nanostructure and covering the first protection feature.

17. The semiconductor structure as claimed in claim 16, further comprising:
a source/drain feature adjoining the second nanostructure;
a contact plug below the source/drain feature; and
second protection features over the isolation structure and surrounding the contact plug, wherein the first protection feature and the second protection features are made of a continuous dielectric material.

18. The semiconductor structure as claimed in claim 16, wherein the second protection features are thicker than the first protection feature.

19. The semiconductor structure as claimed in claim 16, further comprising:
a SiGe layer between the lower fin element and the first nanostructure; and
an inner spacer layer sandwiched between the SiGe layer and the contact plug.

20. The semiconductor structure as claimed in claim 16, wherein the first nanostructure is thicker than the second nanostructure.
